(19) United States
(12) Patent Application Publication
(10) Pub. No.: US 2025/0343117 A1
(43) Pub. Date: Nov. 6, 2025

(54) SEMICONDUCTOR DEVICES HAVING METAL GATE RUNNERS WITH ASYMMETRIC OUTER GATE RUNNERS, UNEVENLY-SPACED INNER GATE RUNNERS AND/OR SPINE-RIB INNER GATE RUNNERS WITH MULTIPLE RIBS

(71) Applicant: Wolfspeed, Inc., Durham, NC (US)

(72) Inventors: Michael Maas, Apex, NC (US); Stephen Tovcimak, Clifton Park, NY (US); Daniel Richter, Raleigh, NC (US); Isauro Amaro, Tempe, AZ (US)

(21) Appl. No.: 18/655,542

(22) Filed: May 6, 2024

(51) Int. Cl. H01L 23/482; H01L 29/06; H01L 29/16; H01L 29/78

(52) U.S. Cl. CPC H01L 23/4824; H10D 30/665; H10D 30/668; H10D 62/107; H10D 62/109; H10D 62/115; H10D 62/127; H10D 62/8325

(57) ABSTRACT

Semiconductor devices comprise a semiconductor layer structure having an active region therein, a gate pad on the semiconductor layer structure and positioned to be closest to a first side of the active region, a plurality of gate electrodes, and a metal gate runner that electrically connects the gate pad to at least some of the gate electrodes. The metal gate runner comprises an outer runner that extends around a portion of a periphery of the active region. The outer gate runner comprises a first outer segment that extends along at least a portion of the first side of the active region and a second outer segment that extends along at least a portion of a second side of the active region that connects to the first side, but the outer gate runner does not extend along a third side of the active region that is opposite the second side.

### FIELD

The present invention relates to semiconductor devices and, more particularly, to power semiconductor devices and to methods of fabricating such devices.

### BACKGROUND

The Metal Oxide Semiconductor Field Effect Transistor (“MOSFET”) is a well-known type of semiconductor transistor that may be used as a switch. A MOSFET is a three terminal device that has gate, drain and source terminals and a semiconductor body. The semiconductor body is referred to herein as a “semiconductor layer structure” and may include one or more semiconductor layers/regions. A source region that is electrically connected to the source terminal and a drain region that is electrically connected to the drain terminal are formed in the semiconductor layer structure. A channel region is formed in the semiconductor layer structure in between the source region and the drain region. A gate electrode that is electrically connected to the gate terminal is disposed adjacent the channel region and separated from the channel region by a thin oxide layer. A MOSFET may be turned on or off by setting a gate bias voltage that is applied to the gate electrode (through the gate terminal) to be above or below a threshold value. When the gate bias voltage exceeds the threshold value, the MOSFET is turned on (i.e., it is in its “on-state”), and current is conducted through the channel region between the source and drain regions. When the gate bias voltage is reduced below the threshold level, the MOSFET turns off and current ceases to conduct through the channel region.

An n-type MOSFET has source and drain regions that have n-type (electron) conductivity and a channel region that has p-type (hole) conductivity (i.e., an “n-p-n” design). An n-type MOSFET turns on when a gate bias voltage is applied to the gate electrode that is sufficient to create a conductive n-type inversion layer in the p-type channel region, thereby electrically connecting the n-type source and drain regions and allowing for majority carrier conduction therebetween. A p-type MOSFET has a “p-n-p” design (i.e., p-type source and drain regions and an n-type channel region) and turns on when a gate bias voltage is applied to the gate electrode that is sufficient to create a conductive p-type inversion layer in the n-type channel region to electrically connect the p-type source and drain regions. Herein, the terms “first conductivity type” and “second conductivity type” are used to indicate either n-type or p-type, where the first and second conductivity types are different. Thus, if a first region of a device has a first conductivity type and a second region of the device has a second conductivity type, this means either that the first region has n-type conductivity and the second region has p-type conductivity or, alternatively, that first region has p-type conductivity and the second region has n-type conductivity.

As noted above, the gate electrode of a MOSFET is separated from the channel region by a thin oxide layer that is called a gate oxide layer. Other non-oxide gate dielectric layers may be used in certain applications in place of the gate oxide layer. It will be appreciated that the techniques according to embodiments of the present invention that are described herein are equally applicable to devices having gate dielectric layers formed with materials other than oxides.

Because the gate electrode of a MOSFET is insulated from the channel region by the gate oxide layer, minimal gate current is required to maintain the MOSFET in its on-state or to switch the MOSFET between its off-state and its on-state. The gate current is kept small during switching because the gate forms a capacitor with the channel region. Thus, only minimal charging and discharging current is required during switching, allowing for less complex gate drive circuitry and faster switching speeds. MOSFETs may be stand-alone devices or may be combined with other circuit devices. For example, an Insulated Gate Bipolar Transistor (“IGBT”) is a semiconductor device that includes both a MOSFET and a Bipolar Junction Transistor (“BJT”) that combines the high impedance gate electrode of the MOSFET with the small on-state conduction losses that may be provided by a BJT. The base current of the BJT is supplied through the channel of the MOSFET, thereby allowing a simplified external drive circuit (since the drive circuit only charges and discharges the gate electrode of the MOSFET).

In some applications, MOSFETs or other semiconductor devices such as IGBTs or Junction Field Effect Transistors (“JFETs”) may need to carry large currents and/or be capable of blocking high voltages. Such semiconductor devices are often referred to as “power” semiconductor devices. Power semiconductor devices are often fabricated from wide band-gap semiconductor materials (herein, the term “wide band-gap semiconductor” encompasses any semiconductor having a band-gap of at least 1.4 eV) such as silicon carbide (“SiC”), which has a number of advantageous characteristics including, for example, a high electric field breakdown strength, high thermal conductivity, high electron mobility, high melting point and high-saturated electron drift velocity.

Power semiconductor devices such as power MOSFETs can have a lateral structure or a vertical structure. In a power semiconductor device having a “lateral” structure, the terminals of the device (e.g., the drain, gate and source terminals for a power MOSFET) are on the same major surface (i.e., top or bottom) of a semiconductor layer structure. In contrast, in a device having a “vertical” structure, at least one terminal is provided on each major surface of the semiconductor layer structure (e.g., in a vertical power MOSFET, the source and gate terminals may be on the top surface of the semiconductor layer structure and the drain terminal may be on the bottom surface of the semiconductor layer structure). The semiconductor layer structure may or may not include an underlying substrate such as a growth substrate.

The semiconductor layer structure of a power semiconductor device typically includes an “active region” in which one or more functional semiconductor devices are formed. The active region acts as a main junction for blocking voltage during reverse bias (off-state) operation and providing current flow during forward bias (on-state) operation. The power semiconductor device may also have an edge termination structure such as, for example, guard rings or a junction termination extension, in a termination region of the semiconductor layer structure that is adjacent (and typically surrounding) the active region. The edge termination structure may, among other things, reduce electric field crowding effects that can occur at the outer edges of a power semiconductor device. Typically, multiple power semiconductor devices are formed in/on a common wafer, and each power semiconductor device will typically have its own edge termination structure. After the wafer is fully processed, the resultant structure may be diced to separate the individual edge-terminated power semiconductor devices. Each power semiconductor device may have a unit cell structure in which the active region of each power semiconductor device includes a plurality of individual “unit cell” devices that are electrically connected in parallel and that together function as a single power semiconductor device.

FIGS. 1A-1C illustrate three example gate structures for silicon carbide based power MOSFETs. In particular, FIGS. 1A-1C are schematic plan (i.e., top) views of three power MOSFETs 10A, 10B and 10C in which various of the upper metal and dielectric layers are omitted so that the respective gate pads 20A, 20B, 20C, the respective metal gate runners 30A, 30B, 30C and the respective gate electrodes 40A, 40B, 40C are visible. The gate pads 20A, 20B, 20C may be metal pads that act as the gate terminal for the respective power MOSFETs 10A, 10B, 10C. Each gate pad 20A, 20B, 20C may be formed on a respective polysilicon pad (not visible in the figures). The gate structure designs of FIGS. 1A and 1C are conventional, while FIG. 1B illustrates another possible, but unconventional design.

As shown in FIGS. 1A-1C, the metal gate runners 30A, 30B, 30C electrically connect to the respective gate pads 20A, 20B, 20C. Polysilicon runners (not visible in the figures) may be formed underneath the respective metal gate runners 30A, 30B, 30C. The gate electrodes 40A, 40B, 40C extend from the respective metal gate runners 30A, 30B, 30C and from the gate pads 20A, 20B, 20C. The regions where the gate electrodes 40A, 40B, 40C are provided correspond to the active regions 12A, 12B, 12C of the respective power MOSFETs 10A, 10B, 10C.

Referring to FIG. 1A, the metal gate runner 30A for power MOSFET 10A includes an outer gate runner 32A that has a first outer segment 34A-1 that extends horizontally (i.e., in the x-direction) to the left from an upper left side of the gate pad 20A, a second outer segment 34A-2 that extends vertically (i.e., in the y-direction) from a distal end of the first outer segment 34A-1, a third outer segment 34A-3 that extends horizontally (i.e., in the x-direction) to the right from an upper right side of the gate pad 20A, and a fourth outer segment 34A-4 that extends vertically (i.e., in the y-direction) from a distal end of the third outer segment 34A-3. The metal gate runner 30A further includes an inner gate runner 36A that has a first inner segment 38A-1 that extends vertically from a lower center portion of the gate pad 20A. The gate electrodes 40A extend horizontally (i.e., in the x-direction) between the second outer segment 34A-2 and the gate pad 20A, between the second outer segment 34A-2 and the first inner segment 38A-1, between the fourth outer segment 34A-4 and the gate pad 20A, and between the fourth outer segment 34A-4 and the first inner segment 38A-1.

In power MOSFET 10B of FIG. 1B, the metal gate runner 30B includes an inner gate runner 36B that has a first inner segment 38B-1 that extends vertically from a lower center portion of the gate pad 20B. The metal gate runner 30B further includes an outer gate runner 32B that has a first outer segment 34B-1 that extends horizontally (i.e., in the x-direction) to the left from an upper left side of the gate pad 20B, a second outer segment 34B-2 that extends horizontally (i.e., in the x-direction) to the right from an upper right side of the gate pad 20B, and a third outer segment 34B-3 that extends horizontally in both directions from a distal end of the first inner segment 38B-1. The gate electrodes 40B extend vertically (i.e., in the y-direction) between the first outer segment 34B-1 and the third outer segment 34B-3, between the gate pad 20B and the third outer segment 34B-1, and between the second outer segment 34B-2 and the third outer segment 34B-3.

In power MOSFET 10C of FIG. 1C, the metal gate runner 30C includes an outer gate runner 32C that has a first outer segment 34C-1 that extends horizontally (i.e., in the x-direction) to the left from an upper left side of the gate pad 20C, a second outer segment 34C-2 that extends vertically (i.e., in the y-direction) from a distal end of the first outer segment 34C-1, a third outer segment 34C-3 that extends horizontally (i.e., in the x-direction) to the right from an upper right side of the gate pad 20C, and a fourth outer segment 34C-4 that extends vertically (i.e., in the y-direction) from a distal end of the third outer segment 34C-3. The metal gate runner 30C further includes an inner gate runner 36C that has a first inner segment 38C-1 that extends vertically from a lower center portion of the gate pad 20C. Power MOSFET 10C includes a first plurality of gate electrodes 40C that extend horizontally (i.e., in the x-direction) in the exact same manner as the gate electrodes 40A of power MOSFET 10A, and also includes a second plurality of gate electrodes 40C that extend vertically (i.e., in the y-direction) so that the gate electrodes 40C have a so-called “mesh” design where gate electrodes 40C extend in both the x-direction and the y-direction across the active region 12C.

When a gate signal is input to the gate pad 20A, 20B, 20C of any of power MOSFETs 10A, 10B, 10C, the gate signal flows to the respective metal gate runner 30A, 30B, 30C, and from the metal gate runners 30A, 30B, 30C to the gate electrodes 40A, 40B, 40C.

As discussed above, the gate electrodes 40A, 40B, 40C in conventional silicon carbide based power MOSFETs are typically formed of polysilicon. Since the resistance of polysilicon is orders of magnitude greater than the resistance of a metal such as aluminum, the gate signals pass along the gate electrodes 40A, 40B, 40C relatively slowly, which negatively impacts the switching speed of the power MOSFET. The metal gate runners 30A, 30B, 30C provide a low-resistance path between the metal gate pads 20A, 20B, 20C and the gate electrodes 40A, 40B, 40C, which improves the switching performance. The gate signals will almost entirely flow along the metal gate runners 30A, 30B, 30C (since metal is much less resistive than polysilicon) as the signal passes from the gate pads 20A, 20B, 20C to the gate electrodes 40A, 40B, 40C. Herein the term “metal gate runner” encompasses both metal gate runners and metal silicide gate runners.

A wide variety of different metal gate runner designs are known in the art. FIGS. 2A-2K are schematic plan views of various conventional power MOSFETs that show the locations of the metal gate pad and the metal gate runners on the semiconductor layer structure of the device while omitting all other upper dielectric and metallization layers, including the gate electrodes.

FIG. 2A schematically illustrates a conventional power MOSFET 50A. As shown, power MOSFET 50A does not include a metal gate runner, and hence the gate signal flows directly from the gate pad 60A to the gate electrodes (not shown) either directly (if the gate power MOSFET 50A has a mesh gate electrode design) or via polysilicon runners (not shown). The gate pad 60A is positioned within the active region 107 of power MOSFET 50A so that the active region 107 surrounds the gate pad 60A in plan view.

FIG. 2B schematically illustrates another conventional power MOSFET 50B. As shown, in power MOSFET 50B the metal gate pad 60B is positioned along the upper edge of the device, and a metal gate runner 70B is provided that includes an outer gate runner 72B that comprises a first outer segment 74B-1 that extends horizontally to the left from the upper left corner of the metal gate pad 60B along a portion of a first side of the active region 52B, a second outer segment 74B-2 that extends vertically from a distal end of the first outer segment 74B-1 along a portion of a second side of the active region 52B, a third outer segment 74B-3 that extends horizontally to the right from the upper right corner of the metal gate pad 60B along a portion of the first side of the active region 52B, and a fourth outer segment 74B-4 that extends vertically from a distal end of the third outer segment 74B-3 along a portion of a third side of the active region 52B.

FIG. 2C schematically illustrates another conventional power MOSFET 50C. As shown, in power MOSFET 50C a metal gate pad 60C is positioned along the upper edge of the device, and a metal gate runner 70C is provided that includes an inner gate runner 76C that comprises a single inner segment 78C-1. The inner segment 78C-1 extends from the lower middle of the metal gate pad 60C through the active region 52C in the y-direction (also referred to as the “vertical” direction).

FIG. 2D schematically illustrates another conventional power MOSFET 50D that includes a metal gate runner 70D that has both an inner gate runner 76D that comprises a single inner segment 78D-1 that corresponds to inner segment 78C-1 of FIG. 2C and an outer gate runner 72D that comprises first through fourth outer segments 74D-1 through 74D-4 that correspond to the first through fourth outer segments 74B-1 through 74B-4 of FIG. 2B.

FIGS. 2E and 2F illustrate two additional conventional power MOSFETs 50E, 50F that include respective metal gate runners 70E, 70F that each have a respective inner gate runner 76E, 76F that comprises multiple inner segments 78E, 78F. In particular, power MOSFET 50E positions the metal gate pad 60E thereof along the upper edge of the device, and has a metal gate runner 70E that comprises an outer gate runner 72E that has first through fourth outer segments 74E-1 through 74E-4 that are essentially identical to first through fourth outer segments 74B-1 through 74B-4 in FIG. 2B, as well as an inner gate runner 76E that comprises a first inner segment 78E-1 that extends in the y-direction across the active region 52E from the first outer segment 74E-1 and a second inner segment 78E-2 that extends in the y-direction across the active region 52E from a lower central portion of the metal gate pad 60E. Power MOSFET 50F is similar to power MOSFET 50E, but the gate pad 60F is inset from the upper edge of the device so that the metal gate runner 70F only includes am inner gate runner 76F that comprises second and third inner segments 74F-2, 74F-3 that extend in the y-direction across the active region 52F and a first inner segment that 74F-1 that connects the second inner segment 74F-2 to the gate pad 60F. The metal gate runner 70F of power MOSFET 50F does not include any outer gate runner, although an outer gate runner having the design of the outer gate runner 72E of FIG. 2E could be added.

FIGS. 2G and 2H illustrate two more conventional power MOSFETs 50G, 50H that include respective metal gate runners 70G, 70H that have “horizontal” inner segments (i.e., inner segments that run across the active region in the x-direction). In power MOSFET 50G the gate pad 60G is positioned along the upper edge of the device, and the metal gate runner 70G includes an outer gate runner 72G that comprises first through sixth outer segments 74G-1 through 74G-6, as well as an inner gate runner 76G that comprises a first inner segment 78G-1 that extends in the x-direction along from the lower left edge of the gate pad 60G, a second inner segment 78G-2 that extends in the x-direction along from the lower right edge of the gate pad 60G, a third inner segment 78G-3 that extends across the active region 52G in the x-direction from the second outer segment 74G-2, and a fourth inner segment 78G-4 that extends across the active region 52G in the x-direction from the fifth outer segment 74G-5. Power MOSFET 50H is similar to power MOSFET 50G, but includes an inner gate runner 76H that has five horizontal inner segments 78H-1 through 78H-5, where the first and second inner segment 78H-1, 78H-2 extend in the x-direction from the respective lower left and right edges of the gate pad 60H, the fourth inner segment 78H-4 extends across the active region 52H from the fourth outer segment 74H-4 of the outer gate runner 72H, and third and fifth inner segments 78H-3, 78H5 extend across the active region 52H from the second outer segment 74H-2 of the outer gate runner 72H.

FIGS. 21 through 2K illustrate additional conventional power MOSFETs 50I, 50J, 50K that include metal gate runners 70I, 70J, 70K that have both horizontal and vertical inner segments. Power MOSFETs 50I and 50H position the respective gate pads 601, 60J in the upper left corners of the devices, and include metal gate runners 70I, 70J that have respective outer gate runners 721, 72J that each have first through third outer segments 741-1 through 74I-3; 74J-1 through 74J-3. Power MOSFET 50I includes an inner gate runner 76I that includes a horizontal first inner segment 781-1 that extends from the lower right corner of the gate pad 60I, and a vertical second inner segment 781-2 that extends downwardly from the end of the first inner segment 781-1. Power MOSFET 50J includes an inner gate runner 76J that includes a horizontal first inner segment 781-1 that extends downwardly from a middle portion of the second outer segment 74J-2 and vertical second inner segment 78J-2 that extends in both directions from a middle portion of the first inner segment 78J-1. Finally, power MOSFET 50K includes a metal gate runner 70K that includes an inner gate runner 76K that comprises a vertical first inner segment 78K-1 that extends downwardly from a middle portion of the gate pad 60K and a horizontal second inner segment 78K-1 that extends in both directions from a middle portion of the first inner segment 78K-1.

### SUMMARY

Pursuant to some embodiments of the present invention, semiconductor devices are provided that comprise a semiconductor layer structure having an active region therein; a gate pad on the semiconductor layer structure, the gate pad positioned to be closest to a first side of the active region; a plurality of gate electrodes; and a metal gate runner that electrically connects the gate pad to at least some of the gate electrodes, the metal gate runner comprising an outer runner that extends around a portion of a periphery of the active region. When the semiconductor device is viewed in plan view, the outer gate runner comprises a first outer segment that extends along at least a portion of the first side of the active region and a second outer segment that extends along at least a portion of a second side of the active region that connects to the first side, but the outer gate runner does not extend along a third side of the active region that is opposite the second side.

In some embodiments, when the semiconductor device is viewed in plan view, the outer gate runner does not extend along a portion of the first side of the active region that is in between the gate pad and the third side of the active region.

In some embodiments, when the semiconductor device is viewed in plan view, the outer gate runner does not extend along a fourth side of the active region that is opposite the first side of the active region.

In some embodiments, the metal gate runner further comprises an inner gate runner that includes a plurality of inner segments that extend inwardly from the outer gate runner. In some embodiments, at least some of the inner segments extend at right angles from the second outer segment of the outer gate runner. In some embodiments, the inner segments that extend from the second outer segment of the outer gate runner do not extend all the way to the third side of the active region.

In some embodiments, when the semiconductor device is viewed in plan view, a first distance between two adjacent ones of the inner segments is at least 1.1 times greater or at least 1.5 times greater than a second distance between the fourth side of the active region and a one of the inner segments that is closest to the fourth side of the active region. In some embodiments, the first distance may be between 1.7 and 2.3 times the second distance.

In some embodiments, the second outer segment only extends along a portion of the second side of the active region.

In some embodiments, the outer gate runner includes a third outer segment that extends along more than half of a fourth side of the active region that is opposite the first side.

In some embodiments, the metal gate runner further comprises an inner gate runner that comprises a first inner segment that extends from the gate pad. In some embodiments, the first inner segment extends in parallel to the second outer segment.

In some embodiments, the active region substantially surrounds the gate pad, and the metal gate runner further comprises an inner gate runner that comprises a first inner segment that connects the outer gate runner to the gate pad.

In some embodiments, the outer gate runner only includes a single outer segment that directly connects to the gate pad.

Pursuant to further embodiments of the present invention, semiconductor devices are provided that comprise a semiconductor layer structure having an active region therein; a gate pad on the semiconductor layer structure; a plurality of gate electrodes; and a metal gate runner that electrically connects the gate pad to at least some of the gate electrodes. The metal gate runner comprises an outer gate runner that partly surrounds the active region when the semiconductor device is viewed in plan view, where the outer gate runner only extends along first and second sides of the active region.

In some embodiments, the first side of the active region connects to the second side of the active region.

In some embodiments, the outer gate runner only includes a single outer segment that directly connects to the gate pad.

In some embodiments, the gate pad is positioned to be closest to the first side of the active region, and the outer gate runner does not extend along a third side of the active region that is opposite the second side of the active region. In some embodiments, the outer gate runner extends only part of the way along the second side of the active region.

In some embodiments, the metal gate runner further comprises an inner gate runner that comprises a plurality of inner segments that extend inwardly from the outer gate runner. In some embodiments, at least some of the inner segments extend at right angles from the second outer segment of the outer gate runner.

In some embodiments, when the semiconductor device is viewed in plan view, the outer gate runner does not extend along a fourth side of the active region that is opposite the first side of the active region.

In some embodiments, when the semiconductor device is viewed in plan view, a first distance between two adjacent ones of the inner segments is at least 1.1 times greater than or 1.5 times greater than a second distance between the fourth side of the active region and a one of the inner segments that is closest to the fourth side of the active region. In some embodiments, the first distance is between 1.7 and 2.3 times the second distance.

In some embodiments, the metal gate runner further comprises an inner gate runner that comprises a first inner segment that extends from the gate pad. In some embodiments, the first inner segment extends in parallel to the second outer segment.

In some embodiments, the active region substantially surrounds the gate pad, and the metal gate runner system further comprises a first inner segment that connects the outer gate runner to the gate pad.

Pursuant to additional embodiments of the present invention, semiconductor devices are provided that comprise a semiconductor layer structure comprising an active region therein; a gate pad on the semiconductor layer structure; a plurality of gate electrodes; and a metal gate runner that includes an outer gate runner that electrically connects the gate pad to at least some of the gate electrodes. The outer gate runner includes a plurality of outer segments and only a single one of the outer segments directly connects to the gate pad.

In some embodiments, the plurality of outer segments comprises a first outer segment that extends along at least a portion of the first side of the active region and a second outer segment that extends along at least a portion of a second side of the active region that connects to the first side, and the outer gate runner does not extend along a third side of the active region that is opposite the second side.

In some embodiments, when the semiconductor device is viewed in plan view, the outer gate runner does not extend along a fourth side of the active region that is opposite the first side of the active region.

In some embodiments, the metal gate runner further comprises an inner gate runner that comprises a plurality of inner segments that extend from the outer gate runner.

In some embodiments, when the semiconductor device is viewed in plan view, a first distance between two adjacent ones of the inner segments is at least 1.1 times greater than or at least 1.5 times greater than a second distance between the fourth side of the active region and a one of the inner segments that is closest to the fourth side of the active region. In some embodiments, the first distance is between 1.7 and 2.3 times the second distance.

In some embodiments, the outer gate runner includes a third outer segment that extends along more than half of a fourth side of the active region that is opposite the first side.

In some embodiments, the metal gate runner further comprises an inner gate runner that comprises a first inner segment that extends from the gate pad. In some embodiments, the first inner segment extends in parallel to the second outer segment.

Pursuant to yet additional embodiments of the present invention, semiconductor devices are provided that comprise a semiconductor layer structure having an active region therein; a gate pad on the semiconductor layer structure; a plurality of gate electrodes; and a metal gate runner that electrically connects the gate pad to at least some of the gate electrodes, the metal gate runner not extending along a first side of the active region. The metal gate runner comprises an inner gate runner that comprises a plurality of inner segments that extend in parallel to each other and to the first side of the active region when the semiconductor device is viewed in plan view, where a first distance between two adjacent ones of the plurality of inner segments is at least 1.1 times greater than a second distance between the first side of the active region and a one of the plurality of inner segments that is closest to the first side of the active region.

In some embodiments, the first distance is at least 1.5 times greater than the second distance. In some embodiments, the first distance is between 1.7 and 2.3 times the second distance.

In some embodiments, the metal gate runner further comprises an outer gate runner that includes a plurality of outer segments. In some embodiments, only a single one of the outer segments directly connects to the gate pad.

In some embodiments, the plurality of inner segments that extend in parallel to each other each extend from a first of the outer segments. In some embodiments, the plurality of inner segments that extend in parallel to each other each extend more than half way across the active region.

In some embodiments, at least one of the plurality of inner segments extends from the gate pad.

Pursuant to some embodiments of the present invention, semiconductor devices are provided that comprise a semiconductor layer structure having an active region therein; a gate pad on the semiconductor layer structure; a plurality of gate electrodes; and a metal gate runner that electrically connects the gate pad to at least some of the gate electrodes. The metal gate runner includes a first segment and a second segment that is adjacent the first segment, the first and second segments extending in parallel to each other and to a first side of the active region which does not include any segment of the metal gate runner, and a first distance between the first and second segments is at least 1.1 times greater than a second distance between the first side of the active region and a one of the first and second segments that is closest to the first side of the active region.

In some embodiments, the first distance is at least 1.5 times greater that a second distance. In some embodiments, the first distance is between 1.7 and 2.3 times the second distance.

In some embodiments, the metal gate runner comprises an outer gate runner and an inner gate runner, and the first segment is a first outer segment of the outer gate runner and the second segment is a first inner segment of the inner gate runner. In some embodiments, the first inner segment directly connects to the gate pad. In some embodiments, the first outer segment is longer than the first inner segment.

In some embodiments, the metal gate runner comprises an inner gate runner, and the first segment is a first inner segment of the inner gate runner and the second segment is a second inner segment of the inner gate runner.

Pursuant to some embodiments of the present invention, semiconductor devices are provided that comprise a semiconductor layer structure having an active region therein; a gate pad on the semiconductor layer structure; a plurality of gate electrodes; and a metal gate runner that electrically connects the gate pad to at least some of the gate electrodes. The metal gate runner comprises an outer gate runner having a first outer segment and an inner gate runner that comprises a plurality of inner segments that extend from the first outer segment in parallel to each other when the semiconductor device is viewed in plan view, where a first distance between the gate pad and a one of the plurality of inner segments that is closest to the gate pad is less than a second distance between two adjacent ones of the plurality of inner segments.

In some embodiments, the metal gate runner does not extend along a first side of the active region. In some embodiments, a third distance between one of the plurality of inner segments that is closest to the first side of the active region is less than the second distance.

In some embodiments, the outer gate runner further comprises a second outer segment that is interposed on the electrical path between the gate pad and the first outer segment. In some embodiments, the second outer segment directly connects to the gate pad. In some embodiments, the second outer segment is the only outer segment of the outer gate runner that directly connects to the gate pad.

In some embodiments, at least some of the plurality of inner segments extend more than half of the way across the active region.

Pursuant to still further embodiments of the present invention, semiconductor devices are provided that comprise a semiconductor layer structure having an active region therein; a gate pad on the semiconductor layer structure; a plurality of gate electrodes; and a metal gate runner that electrically connects the gate pad to at least some of the gate electrodes, where the metal gate runner comprises an inner gate runner that comprises a first inner segment that extends from the gate pad, a second inner segment that is perpendicular to the first inner segment and that intersects the first inner segment, and a third inner segment that is perpendicular to the first inner segment and that intersects the first inner segment.

In some embodiments, the semiconductor device further comprises a first source bond pad that is at least partially positioned in between the second inner segment and the third inner segment when the semiconductor device is viewed in plan view. In some embodiments, the inner gate runner further comprises a fourth inner segment that is perpendicular to the first inner segment and that intersects the first inner segment. In some embodiments, the semiconductor device further comprises a second source bond pad that is at least partially positioned in between the third inner segment and the fourth inner segment when the semiconductor device is viewed in plan view. In some embodiments, the semiconductor device further comprises a third source bond pad that is at least partially positioned in between the second inner segment and the gate pad when the semiconductor device is viewed in plan view.

In some embodiments, the metal gate runner further comprises an outer gate runner that comprises a first outer segment that extends in parallel to the second inner segment and to the third inner segment. In some embodiments, the first outer segment intersects a distal end of the first inner segment.

In some embodiments, the first outer segment directly connects to the gate pad. In some embodiments, the metal gate runner has a spine and rib configuration.

### BRIEF DESCRIPTION OF DRAWINGS

FIGS. 1A-1C are schematic plan views of three conventional power MOSFETs that illustrate the gate structure of each MOSFET.

FIGS. 2A-2K are schematic plan views of a variety of conventional power MOSFETs that show the locations of the gate pad and the metal gate runners on the semiconductor layer structure of the device.

FIG. 3A is a schematic top view of a silicon carbide power MOSFET according to certain embodiments of the present invention.

FIG. 3B is a schematic top view of the silicon carbide power MOSFET of FIG. 3A with various of the upper metal and dielectric layers removed.

FIG. 3C is a schematic top view of the portion of the silicon carbide power MOSFET of FIG. 3B shown in the box labelled A in FIG. 3B.

FIG. 3D is a schematic cross-sectional view taken along the line 3D-3D of FIG. 3C with portions of the upper metallization and dielectric layers of the power MOSFET added for context.

FIG. 3E is a schematic cross-sectional view taken next to the box labeled A in FIG. 3B.

FIGS. 4A-4C are schematic top views of modified versions of the silicon carbide power MOSFET of FIGS. 3A-3E that show the locations of the gate pad and the metal gate runners on the semiconductor layer structure.

FIG. 5 is a schematic top view of a conventional power MOSFET that has a metal gate runner with an inner gate runner.

FIG. 6 is a schematic top view of a power MOSFET according to embodiments of the present invention.

FIGS. 7A and 7B are schematic top views of power MOSFETs according to embodiments of the present invention that have metal gate runners with metal gate runners that have unevenly-spaced segments.

FIG. 8A is a schematic top view of a power MOSFET according to embodiments of the present invention that has a metal gate runner that comprises an inner gate runner that includes a spine and multiple ribs.

FIG. 8B is a schematic top view of a power MOSFET of FIG. 8A that shows the gate and source pads and the bond wires connecting thereto.

FIGS. 9A-9B are schematic top views of modified versions of the silicon carbide power MOSFET of FIG. 8A that show the locations of the gate pad and the metal gate runners on the semiconductor layer structure.

FIG. 10 is a schematic cross-sectional view of a gate trench power semiconductor device according to embodiments of the present invention.

Two-part reference numerals that include a hyphen are used herein in some instances to distinguish between different ones of multiple like elements. The full two-part reference numeral may be used in the description to refer to individual of these elements, while the first part of the reference numeral may be used to refer to the elements collectively.

### DETAILED DESCRIPTION

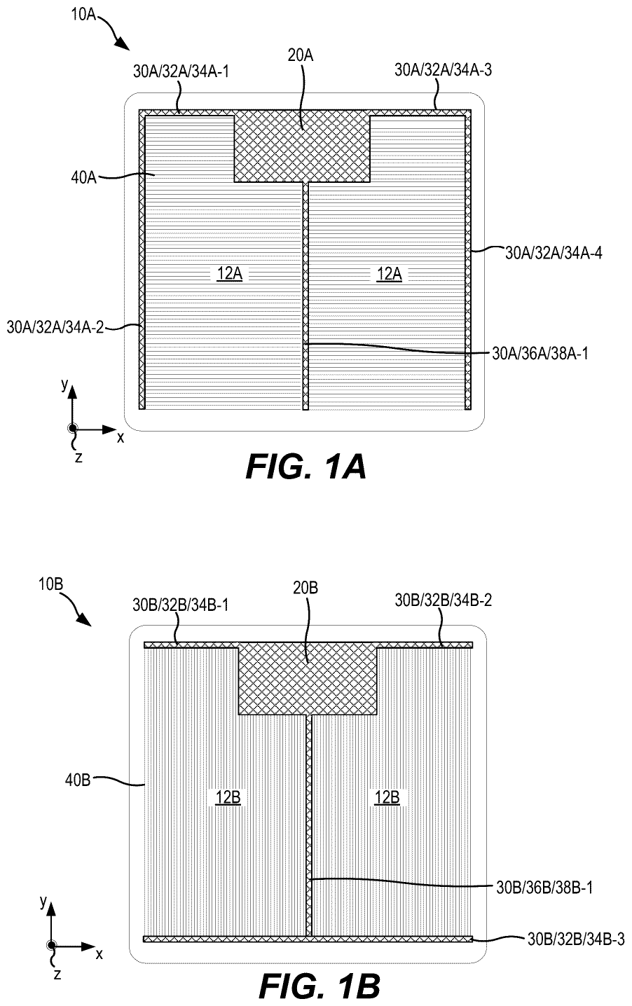

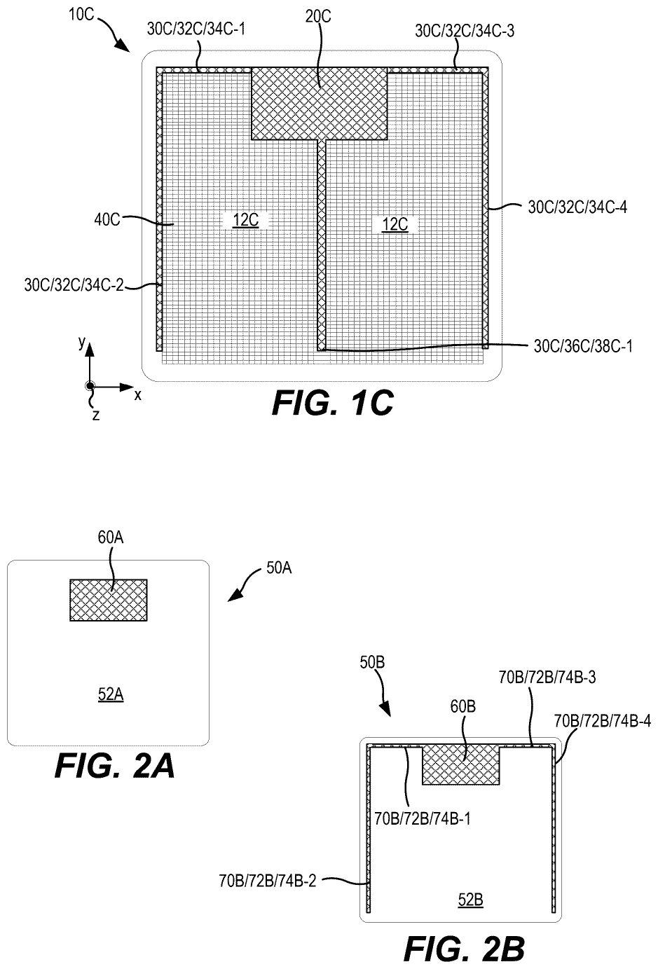

The present invention stems, in part, from a realization that the addition of metal gate runners to a power semiconductor device involves inherent performance tradeoffs. As discussed above, adding metal gate runners to a power semiconductor device advantageously increases the switching speed of the device (and thus reduces switching losses). However, the addition of metal gate runners reduces the size of the active region, at least in devices having a mesh gate electrode design such as shown in FIG. 1C above, and metal gate runners that include an inner gate runner reduce the amount of active area in power semiconductor devices having both mesh and non-mesh gate electrode designs. A reduction in the size of the active region disadvantageously increases the on-state resistance of the device, and the addition of metal gate runners having inner gate runners may also negatively impact the ability to have as many source bond wires as may be desired (which also can negatively impact the performance of the device). Increases in the on-state resistance may increase conduction losses.

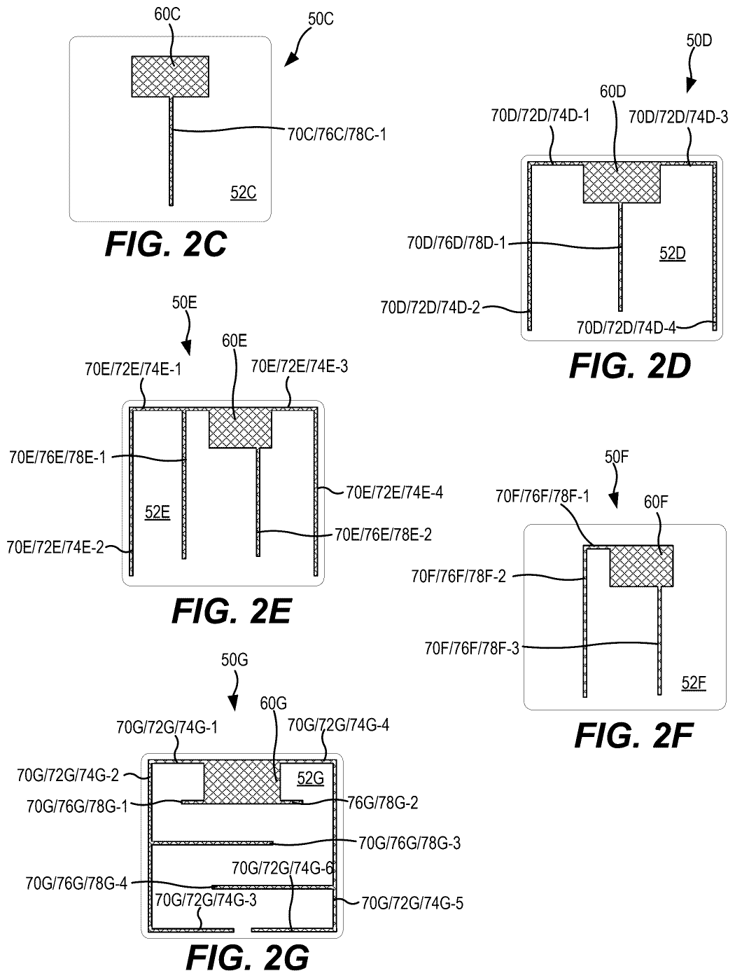

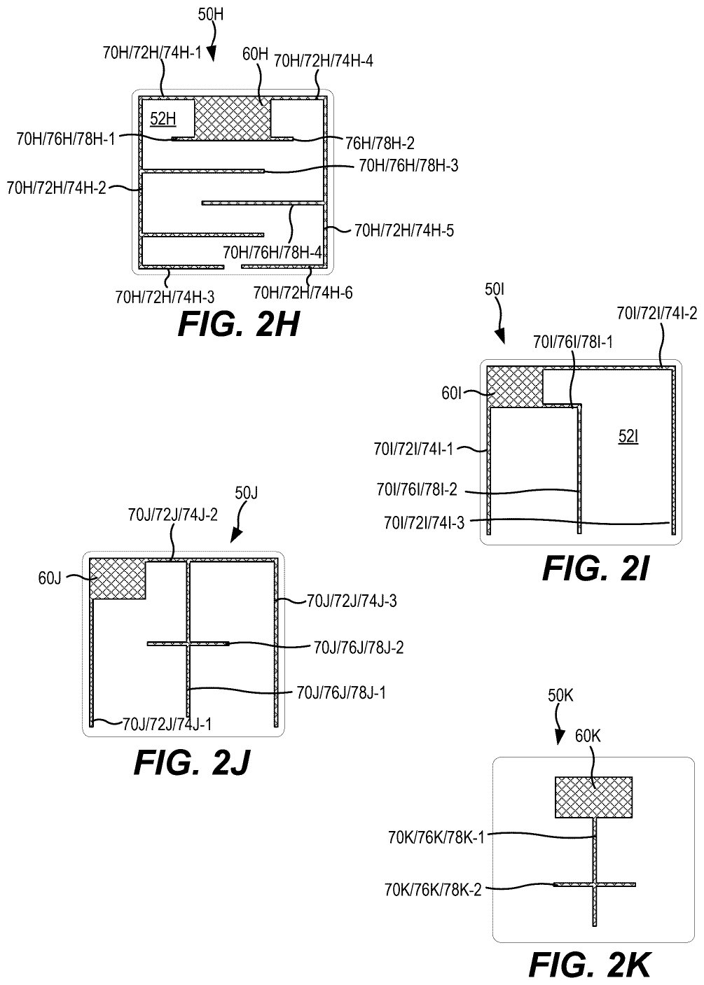

The conventional metal gate runner designs discussed above with reference to FIGS. 2A-2K typically do not provide an optimum tradeoff between, for example, switching speed and on-state resistance performance. For example, the conventional metal gate runner designs shown in FIGS. 2A-2K all either include metal gate runners that have no outer gate runner or that have an outer gate runner that has outer segments that connect to opposed sides of the gate pad (i.e., two outer segments directly connect to the gate pad). This typically results in symmetrical designs, but may not be optimum in many cases. In other words, the benefit provided by an outer gate runner that has outer segments that connect to opposed sides of the gate pad in terms of increased switching speed may often not be worth the reduction in the size of the active region and the commensurate increase in the on-state resistance. Likewise, the conventional metal gate runner designs shown in FIGS. 2A-2K that include inner gate runners that have inner segments that are positioned so that the distances between adjacent parallel inner segments and between end inner segments and adjacent parallel sides of the active region are approximately equal. This may also be sub-optimal.

Pursuant to embodiments of the present invention, vertical power silicon carbide MOSFETs and other vertical power semiconductor devices (e.g., IGBTs) are provided that have improved tradeoffs between switching and on-state resistance performance. In some embodiments, the power semiconductor devices have metal gate runners that include outer gate runners that have a single outer segment that directly connects to the gate pad. As a result, the outer gate runner may, for example, only extend along first and second adjacent (i.e., connected) sides of the active region. By providing a metal gate runner that only directly connects to the gate pad at a single location the tradeoff between switching speed and on-state resistance may be improved for many applications.

According to further embodiments of the present invention, vertical power semiconductor devices are provided that have metal gate runners in which the spacings between adjacent parallel segments are different than the spacing between sides of the active region and the closest parallel segments of the metal gate runner. This approach may reduce the maximum distance that the gate signal must travel along the gate electrodes which may increase the switching speed of the device, and may do so without any loss in other performance parameters.

According to still further embodiments of the present invention, vertical power semiconductor devices are provided that have metal gate runners that have inner gate runners that comprise a “spine” inner segment and a plurality of “rib” inner segments that intersect the spine. These devices include wire bonds that extend in parallel to the ribs.

The techniques disclosed herein may be used in power semiconductor devices having either planar gate electrodes or trench gate designs. The power semiconductor devices according to embodiments of the present invention may exhibit improved trade-offs between the on-state resistance and switching speed.

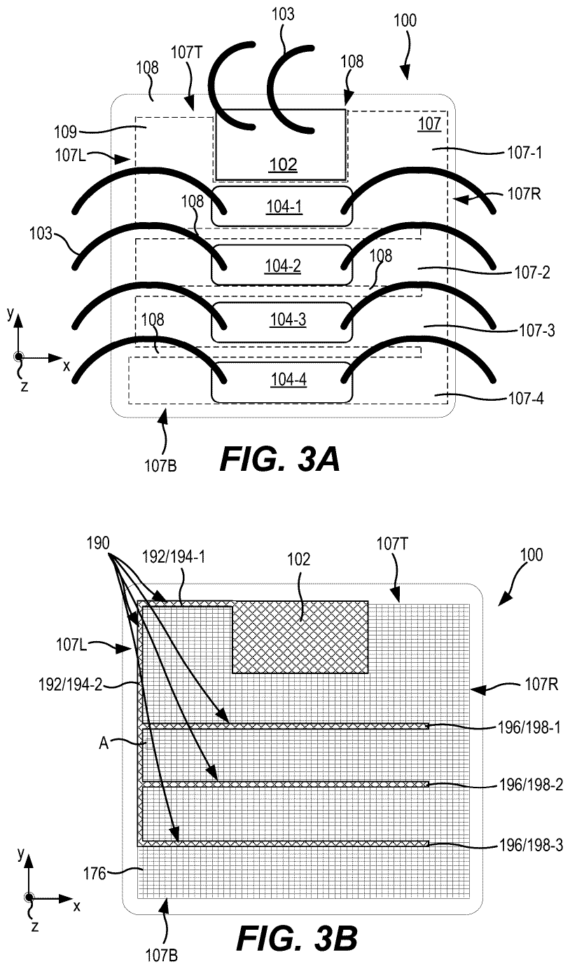

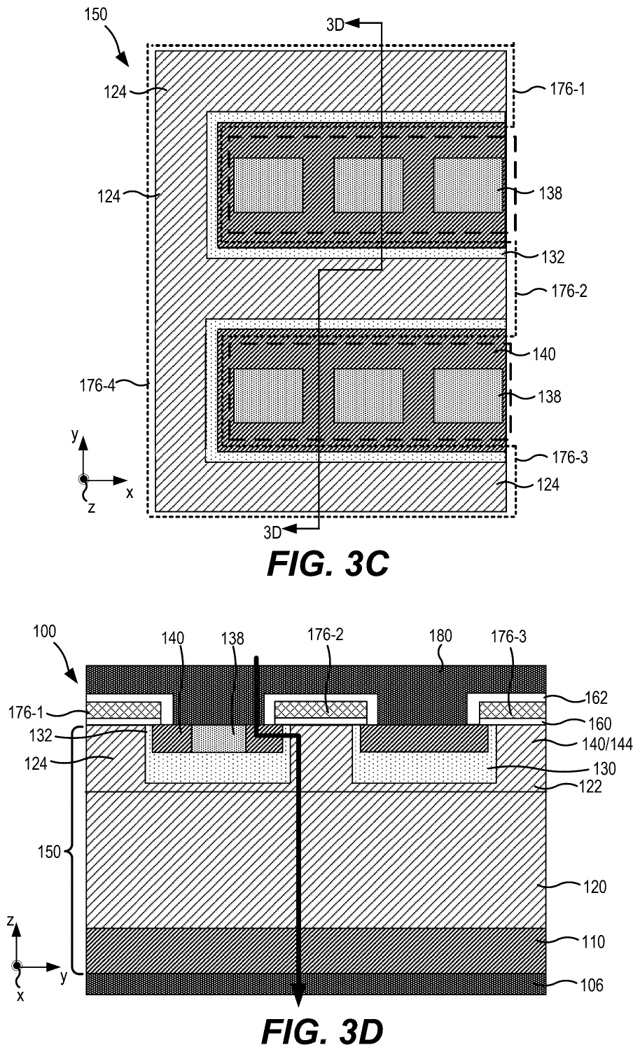

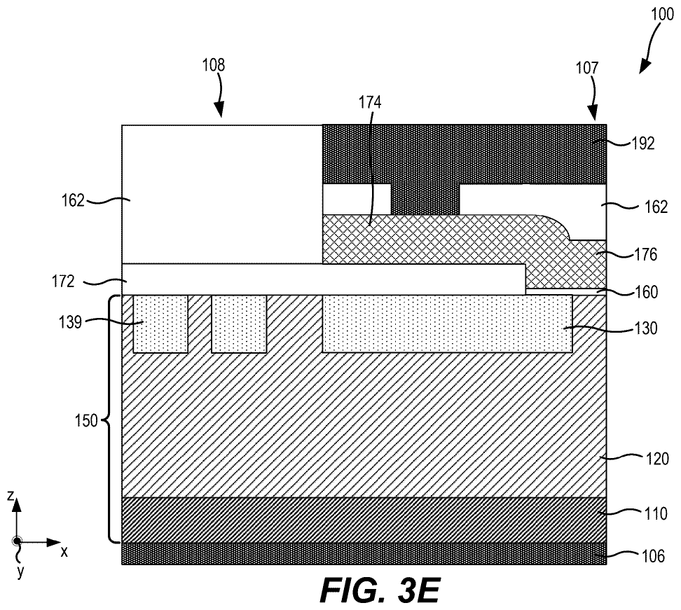

Example embodiments of power semiconductor devices according to embodiments of the present invention will now be described with reference to FIGS. 3A-10. It will be appreciated that features of the different embodiments disclosed herein may be combined in any way to provide many additional embodiments. Thus, it will be appreciated that various features of the present invention are described below with respect to specific examples, but that these features may be added to other embodiments and/or used in place of example features of other embodiments to provide many additional embodiments. Thus, the present invention should be understood to encompass these different combinations. Additionally, while the example embodiments focus on MOSFET implementations, it will be appreciated that the same techniques may be used in other gate trench power semiconductor devices such as insulated gate bipolar transistors (IGBTs), gate-controlled thyristors and the like.

FIG. 3A is a schematic top view of a vertical silicon carbide power MOSFET 100 according to certain embodiments of the present invention. FIG. 3B is a schematic plan view of the power MOSFET 100 with various upper metal and dielectric layers thereof omitted. FIG. 3C is a schematic top view of the portion of the power MOSFET 100 of FIG. 3B shown in the box labelled A in FIG. 3B. FIG. 3D is a schematic cross-sectional view of about two unit cells of the power MOSFET 100 that is taken along line 3D-3D of FIG. 3C. FIG. 3E is a schematic cross-sectional view taken adjacent the box labelled A in FIG. 3B. It will be appreciated that the thicknesses of various of the layers and regions in FIGS. 3A-3E are not necessarily drawn to scale. The same is true with respect to the other figures included in this application.

The power MOSFET 100 includes a semiconductor layer structure 150 (see FIGS. 3C-3E) that comprises one or more semiconductor substrates and/or layers. At least one (and typically all) of the semiconductor layers in the semiconductor layer structure 150 may be silicon carbide layers. Various semiconductor, metal and/or dielectric layers are formed on either side of the semiconductor layer structure 150 and/or embedded in the semiconductor layer structure 150.

As shown in FIG. 3A, the top-side metal layers include a gate pad 102 and a plurality of source pads 104 that are formed on the upper side of the semiconductor layer structure 150. A metal drain pad 106 (see FIGS. 3D-3E) is provided on the bottom side of the semiconductor layer structure 150. The gate pad 102, the source pads 104 and the drain pad 106 form the respective gate, source and drain terminals of power MOSFET 100. The gate and source pads 102, 104 may each be formed of one or more metals, including, for example, a metal such as aluminum that bond wires can be readily attached to via conventional techniques such as thermo-compression or soldering. The drain pad 106 may likewise be a metal pad. A protective layer 109 such as a polyimide layer may cover the entire upper surface of power MOSFET 100 except for the gate and source pads 102, 104.

The source pads 104 may be portions of a source metallization layer 180 (described below) that are exposed through openings in the protective layer 109 or may be separate metal pads. The source metallization layer 180 electrically connects certain regions of the semiconductor layer structure 150 to the source pads 104. The source metallization layer 180 may generally overlic or correspond to an “active region” 107 of the power MOSFET 100 where the unit cell transistors are located. The dashed lines in FIG. 3A illustrate the location of the active region 107 since it is underneath the metal pads 102, 104 and the protective layer 109. An inactive region 108 of power MOSFET 100 surrounds the active region 107 and may also extend into the region defined by the outermost sides of the active region 107 to form inactive regions within the footprint of the active region 107, as shown. The inactive region 108 may include a termination region that extends around the periphery of the MOSFET 100 that includes guard rings, junction termination elements or other termination structures (not shown), a gate pad region that underlies the gate pad 102, and gate runner regions (discussed below) that extend inwardly from the edge of the device to divide the active region 107 into multiple (typically connected) sections 107-1 through 107-4.

Bond wires 103 are shown in FIG. 3A that may be used to connect the gate pad 102 and the source pads 104 to external circuits or the like. The drain pad 106 on the bottom side of power MOSFET 100 may be connected to an external circuit through, for example, an underlying submount (not shown).

FIG. 3B is another plan view of power MOSFET 100 with the source pads 104, the polyimide layer 109, the source metallization layer 180, and various dielectric layers omitted to show the gate electrodes 176 that are formed on the upper surface of the semiconductor layer structure 150 and a metal gate runner 190 that electrically connects the gate pad 102 to the gate electrodes 176. A field oxide layer 172 (FIG. 3E) is provided on the semiconductor layer structure 150 in the inactive region 108 of the MOSFET 100. The field oxide layer 172 may be a relatively thick oxide layer (e.g., ten to twenty times thicker than the gate oxide layers that are discussed below). A polysilicon pattern 170 is provided on the field oxide layer 172 and on selected portions of the active region 107. The portions of the polysilicon pattern 170 that are formed on the field oxide layer 172 may comprise a large polysilicon pad (not shown) that underlies the gate pad 102 and a polysilicon runner 174 (FIG. 3E) that extends from the polysilicon pad to run around much of the periphery of the active region 107 when the power MOSFET 100 is viewed in plan view. The portions of the polysilicon pattern 170 that are provided in the active region 107 form the gate electrodes 176 of the power MOSFET 100. In the depicted power MOSFET 100, the gate electrodes 176 extend both horizontally and vertically across the semiconductor layer structure 150 and hence power MOSFET 100 has a mesh gate electrode design.

Still referring to FIG. 3B, the metal gate runner 190 is provided on and vertically overlaps the polysilicon runner 174. As used herein, two elements of a semiconductor device are considered to “vertically overlap” if an axis that is perpendicular to the major surfaces of a semiconductor layer structure of the semiconductor device intersects both elements. The metal gate runner 190 includes an outer gate runner 192. The outer gate runner 192 refers to portions of the metal gate runner 190 that are positioned between the active region 107 and the termination region. Thus, the outer gate runner 192 refers to the portions of the metal gate runner 190 that are around an outer periphery of the active region 107, and the active region 107 is on only one side of each segment 194 of the outer gate runner 192. The outer gate runner 192 comprises a first outer segment 194-1 that extends from the upper left corner of the gate pad 102 to run along a portion of the upper left side 107L of the active region 107 and a second outer segment 194-2 that extends from a distal end of the first outer segment 194-1 that runs along most of the left side 107L of the active region 107. Each outer segment 194 may be directly connected to another outer segment 194 (if more than one outer segment 194 is provided) or may be indirectly connected to another outer segment 194 (e.g., through the gate pad 102). Each outer segment 194 is a distinct portion of the outer gate runner 192 such as a linear segment or a curved or angled section that connects to other distinct segments.

The metal gate runner 190 further includes an inner gate runner 196. The inner gate runner 196 refers to portions of the metal gate runner 190 that are within a region defined by the sides of the active region 107. The inner gate runner 196 thus defines one or more strips of inactive area within the region defined by the sides of the active region 107, and the active region 107 is on at least two sides of each segment 198 of the inner gate runner 196. The inner gate runner 196 comprises first through third inner segments 198-1 through 198-3 that each extend inwardly from the second outer segment 194-2 to sub-divide the active region 107 into the (connected) sub-regions 107-1 through 107-4 (see FIG. 3A). Each of the first through third inner segments 198-1 through 198-3 may extend more than half way across the active region 107. Each inner segment 198 is a distinct portion of the inner gate runner 196. The inner segments 198 typically extend inwardly from one or more of the outer segments 194 or extend inwardly from the gate pad 102.

The active region 107 typically encompasses well over 50% of the area of the semiconductor die, and often well over 80% of the die area, where the “die area” refers to the area of the die when viewed from above (i.e., in plan view). The inactive region 108 includes a termination region that typically surrounds much or all of the active region 107 when the die is viewed from above as well as regions of the die underneath some or all of the gate pad 102 and/or the metal gate runner 190.

The active region 107 typically extends close to each side of the die. Herein, the “sides” of the active region 107 refer to the portions of the active region 107 that are adjacent the respective sides of the semiconductor die. Thus, the active region 107 of power MOSFET 100 has four sides, namely a first (top) side 107T that includes two discontinuous segments, a second (left) side 107L, a third (right) side 107R and a fourth (bottom) side 107B. As noted above, the termination region typically surrounds much or all of the active region 107 when the die is viewed from above. Thus, the sides of the active region 107 also correspond to respective sides of the termination region (e.g., the second side 107L of the active region 107 is the side of the active region 107 that is adjacent a second side of the termination region.

FIG. 3C is a schematic top view of the upper surface of the semiconductor layer structure 150 of the portion of the silicon carbide power MOSFET 100 of FIG. 3B that is shown in the box labelled A in FIG. 3B. The dotted region in FIG. 3C illustrate the locations of the gate electrodes 176. Portions of three horizontally-extending gate electrodes 176-1 through 176-3 and one vertically extending gate electrode 176-4 are visible in the small region shown in FIG. 3C. The dashed regions in FIG. 3C illustrate the locations where the source metallization layer 180 directly contacts the upper surface of the semiconductor layer structure 150. FIG. 3D is a cross-sectional view taken along line 3D-3D of FIG. 3C. The cross-section of FIG. 3D shows one full unit cell of the MOSFET 100 and portions of two adjacent unit cells. It should be noted that the cross-section of FIG. 3D is not taken along a straight line but instead includes a “jog” to show cross-sections of two different regions of the MOSFET 100.

Referring to FIGS. 3C-3D, the power MOSFET 100 includes an n-type silicon carbide semiconductor substrate 110 such as, for example, a single crystal 4H silicon carbide semiconductor substrate that is heavily-doped with n-type impurities. The n-type doping concentration of the substrate 110 may be, for example, between 1×10¹⁸ atoms/cm³ and 1×10²¹ atoms/cm³, although other doping concentrations may be used. Herein, the “doping concentration” of a semiconductor material refers to the number of dopant atoms that cause the semiconductor material to have a certain conductivity type (i.e., cither n-type or p-type) that are present within a cubic centimeter of semiconductor material as measured using standard measurement techniques such as Secondary Ion Mass Spectrometry (“SIMS”). The doping concentration of a layer or region may be relatively constant or may vary (e.g., be graded with depth), and the doping concentration refers to the peak doping concentration of the layer or region. For an n-type semiconductor material, references to the doping concentration refer to the concentration of n-type dopants and for a p-type semiconductor material, references to the doping concentration refer to the concentration of p-type dopants. The substrate 110 may be any appropriate thickness (e.g., between 100 and 500 microns thick), and it will be appreciated that the substrate 110 will typically be much thicker than shown. The thickness of various other layers of power MOSFET 100 likewise may not be shown to scale in order to allow other portions of the devices to be enlarged in the figures. The substrate 110 may be partially or fully removed in some embodiments.

A lightly-doped n-type silicon carbide drift region 120 is provided on the upper surface of the substrate 110. The n-type silicon carbide drift region 120 may be formed by, for example, epitaxial growth on the silicon carbide substrate 110. The n-type silicon carbide drift region 120 may have, for example, a doping concentration of 1×10¹⁴ to 5×10¹⁶ dopants/cm³. The doping concentration may vary with the voltage blocking rating of the device, with devices having higher voltage blocking ratings typically having lower doping concentrations in the drift region 120. For example, a MOSFET 100 having a voltage blocking rating of 10 kV or more might have a drift region n-type doping concentration of between 1×10¹⁴ to 5×10¹⁴ dopants/cm³, whereas a MOSFET 100 having a voltage blocking rating of 500-1200 V might have a drift region n-type doping concentration of between 1×10¹⁶ to 5×10¹⁶ dopants/cm³. The n-type silicon carbide drift region 120 may be a thick region, having a vertical height above the substrate 110 of, for example, 3-50 microns. An upper portion 122 of the n-type silicon carbide drift region 120 may be more heavily doped than the remainder of the drift region 120 to provide a current spreading layer 122 in an upper portion of the drift region 120. The doping concentration of this current spreading layer 122 may be, for example, about 1.5 to 4.0 times higher than the doping concentration of the remainder of the drift region 120. The current spreading layer 122 may be formed during the epitaxial growth process. Herein, the current spreading layer 122, if provided, is considered to be part of the drift layer 120 and hence will not be discussed separately.

A plurality of p-type well regions 130 (which may also be referred to herein as “p-wells”) are formed in upper portions of the n-type drift region 120. While not shown in the figures, a large p-well 130 may also be formed underneath the portion of the field oxide layer 172 that underlies the gate pad 102 and p-wells 130 may also be formed underneath the polysilicon runner 174. The p-wells 130 may all be interconnected in some embodiments. The p-wells 130 may have a doping concentration of, for example, between 5×10¹⁵ cm⁻³ and 5×10¹⁹ cm⁻³ and, more typically, between 5×100 cm⁻³ and 5×100 cm⁻³. The p-wells 130 may be formed via ion implantation. As known to those skilled in the art, ions such as n-type or p-type dopants may be implanted in a semiconductor layer or region by ionizing the desired ion species and accelerating the ions at a predetermined kinetic energy as an ion beam towards the surface of a semiconductor layer in an ion implantation target chamber. Based on the predetermined kinetic energy, the desired ion species may penetrate into the semiconductor layer. The ions will implant at different depths into the semiconductor layer so that the predetermined kinetic energy will provide an implant “profile” with varying ion concentrations as a function of depth. The dopants may comprise, for example, Al⁺ or N⁺ ions, although any appropriate dopant ions may be used. In some embodiments, the implantation may be performed at different temperatures such as, for example, temperatures of 75° C. or more. It will be appreciated that the p-wells 130 often have a doping concentration that varies with depth. The p-wells 130 in the active region include channel regions 132 (discussed in more detail below) formed therein. These channel regions 132 may be less heavily doped than other portions of the p-well 130.

A plurality of n-type JFET regions 124 are defined in the upper portion of the drift region 120. Each JFET region 124 may comprise a region of n-type material that is typically more heavily doped n-type than the lower portion of the drift region 120. The JFET regions 124 are defined between adjacent p-wells 130 underneath the gate electrodes 176.

A plurality of heavily-doped n-type silicon carbide source regions 140 are formed in upper portions of the p-wells 130. The source region 140 may have a doping concentration of, for example, between 5×10¹⁸ cm⁻³ and 5×10²¹ cm⁻³. In addition, heavily-doped p-type silicon carbide well contact regions 138 are also formed in upper portions of the p-wells 130. As shown, the well contact regions 138 may appear as a plurality of “islands” in each source region 140 when the MOSFET 100 is viewed in plan view. It will be appreciated, however, that in other embodiments the well contact regions 138 may connect to each other along the x-direction so that a single elongated well contact region 138 is provided between each pair of adjacent gate electrodes 176. Other configurations for the well contact and source regions 138, 140 are known in the art and may be used. The well contact regions 138 and the source regions 140 may each be formed via ion implantation. The substrate 110, the drift region 120 (including any current spreading layer 122 and the JFET regions 124), the p-wells 130, the channel regions 132, the well contact regions 138 and the source regions 140 together comprise the semiconductor layer structure 150 of MOSFET 100.

As shown in FIG. 3D, a plurality of gate dielectric layers 160 are formed on the upper surface of the semiconductor layer structure 150. The gate dielectric layers 160 may or may not be connected to each other along the periphery of the MOSFET 100. The gate dielectric layers 160 may comprise, for example, silicon oxide layers, although other insulating materials may be used. The gate electrodes 176 are formed on the respective gate dielectric layers 160. The gate electrodes 176 may comprise, for example, a conductive material such as polysilicon, a silicide or a metal. As discussed above, the gate electrodes 176 may be part of a larger polysilicon pattern 170. One or more intermetal dielectric layers 162 may cover the respective gate electrodes 176. The intermetal dielectric layers 162 may comprise, for example, silicon oxide.

The upper surface of the semiconductor layer structure 150 is exposed in between adjacent intermetal dielectric patterns 162. The source regions 140 and the p-type well contact regions 138 are thus exposed in between adjacent intermetal dielectric patterns 162. A source metallization layer 180 is formed over the upper surface of the MOSFET 100 so that the source metallization layer 180 makes electrical contact to the n-type source regions 140 and the p-type well contact regions 138 while being electrically insulated from the gate electrodes 176 by the intermetal dielectric patterns 162. The source metallization layer 180 may comprise, for example, metals such as nickel, titanium, tungsten and/or aluminum, and/or alloys and/or thin layered stacks of these and/or similar materials. A drain contact 106 is formed on the lower surface of the substrate 110. The drain contact 106 may comprise, for example, the same or similar materials to the source metallization layer 180, and may form an ohmic contact to the silicon carbide substrate 110.

FIG. 3E is a cross-sectional view that illustrates the termination region 108 of MOSFET 100 and the interconnection between the outer gate runner 192 and the gate electrodes 176. As shown in FIG. 3E, the termination region 108 includes a termination structure in the form of a pair of guard rings 139. Each guard ring 139 may be implemented as a moderately-doped or highly-doped p-type region in the upper portion of the semiconductor layer structure 150. Each guard ring 139 may extend completely around the periphery of the active region 107. The left edge of the active region 107 is shown in FIG. 3E.

As is also shown in FIG. 3E, the field oxide layer 172 is formed on the upper surface of the semiconductor layer structure 150 and the polysilicon runner 174 is formed on the field oxide layer 172. A p-well 130 is formed underneath the field oxide layer 172 and vertically overlaps the field oxide layer 172 and the polysilicon runner 174. The intermetal dielectric layer 162 extends onto the upper surface of the polysilicon runner 174. A trench is formed in the intermetal dielectric layer 162 and the outer gate runner 192 is formed on the intermetal dielectric layer 162 and in the trench in the intermetal dielectric layer 162 to electrically connect the outer gate runner 192 to the polysilicon runner 174. The polysilicon runner 174 merges into the ends of the gate electrodes 176 as shown.

As discussed above with reference to FIG. 3B, power MOSFET 100 has a mesh gate electrode design. When a gate signal is applied to the gate pad 102, it may pass directly to the gate electrodes 176 that connect directly to the gate pad 102, and the gate signal will also flow into and along the metal gate runner 190. The amount of gate signal that flows along each possible path will be a function of the resistance of the path. The gate signal will ultimately flow along the length of all of the gate electrodes 176, but since the metal gate runner 190 provides a path having a far lower resistance, the gate signal that is supplied to gate electrodes 176 that are below the first inner segment 198-1 of the inner gate runner 196 will almost exclusively flow along the second outer segment 194-2 of the outer gate runner 192 before flowing into the gate electrode mesh.

The metal gate runner design shown in FIG. 3B may ensure that the gate signal does not have to flow through a long stretch of polysilicon, thereby providing enhanced switching speed. In addition, the amount of die area that is devoted to the metal gate runner 190 is relatively low, so that the power MOSFET 100 will also exhibit relatively low on-state resistance values. Thus, the power MOSFET 100 may provide improved performance as compared to the conventional power MOSFETs discussed above with reference to FIGS. 2A-2K.

Referring again to FIG. 3B, it can be seen that pursuant to some embodiments of the present invention, semiconductor devices such as MOSFET 100 are provided that comprise a semiconductor layer structure 150 having an active region 107 therein, a gate pad 102 on the semiconductor layer structure 150, the gate pad 150 positioned to be closest to a first side 107T of the active region 107, a plurality of gate electrodes 176, and a metal gate runner 190 that electrically connects the gate pad 102 to at least some of the gate electrodes 176. The metal gate runner 190 comprises an outer runner 192 that extends around a portion of a periphery of the active region 107. When the semiconductor device 100 is viewed in plan view, the outer gate runner 192 comprises a first outer segment 194-1 that extends along at least a portion of the first side 107T of the active region 107 and a second outer segment 194-2 that extends along at least a portion of a second side 107L of the active region 107 that connects to the first side 107T, but the outer gate runner 192 does not extend along a third side 107R of the active region 107 that is opposite the second side 107L.

In some embodiments, the outer gate runner 190 does not extend along a portion of the first side 107L of the active region 107 that is in between the gate pad 102 and the third side 107R of the active region 107. In some embodiments, the outer gate runner 190 also docs not extend along a fourth side 107B of the active region 107 that is opposite the first side 107T of the active region 107. In some embodiments, the metal gate runner 190 further comprises an inner gate runner 196 that includes a plurality of inner segments 198 that extend inwardly from the outer gate runner 192. Some or all of the inner segments 198 may extend at right angles from the second outer segment 194-2 of the outer gate runner 192. The inner segments 198 may not extend all the way across the active region 107. In some embodiments, the second outer segment 194-1 may only extend along a portion of the second side 107L of the active region 107. In other embodiments, the outer gate runner 192 may include a third outer segment 194-3 that extends along more than half of the fourth side 107B of the active region 107.

Still referring to FIG. 3B, it can be seen that pursuant to further embodiments of the present invention, semiconductor devices such as MOSFET 100 are provided that comprise a semiconductor layer structure 150 having an active region 107 therein, a gate pad 102 on the semiconductor layer structure 150, a plurality of gate electrodes 176, and a metal gate runner 190 that electrically connects the gate pad 102 to at least some of the gate electrodes 176. In these embodiments, the metal gate runner 190 may comprise an outer gate runner 192 that partly surrounds the active region 107 when the MOSFET 100 is viewed in plan view, and the outer gate runner 192 only extends along first and second adjacent sides 107T, 107L of the active region 107.

Continuing to refer to FIG. 3B, pursuant to further embodiments of the present invention, semiconductor devices such as MOSFET 100 are provided that comprise a semiconductor layer structure 150 having an active region 107 therein, a gate pad 102 on the semiconductor layer structure 150, a plurality of gate electrodes 176, and a metal gate runner 190 that includes an outer gate runner 192 that electrically connects the gate pad 102 to at least some of the gate electrodes 176. In these embodiments, the outer gate runner 192 includes a plurality of outer segments 194 and only a single one of the outer segments 194 directly connects to the gate pad 192. Note that references herein to a segment of the metal gate runner directly connecting (or directly connects) to a gate pad mean that the segment does not connect to the gate pad through any other segment of the metal gate runner. Thus, for example, if a gate resistor were interposed between outer segment 194-1 and the gate pad 102, the outer segment 194-1 would still be considered to “directly connect” to the gate pad. Segments 194-2, 198-1, 198-2 and 198-3 do not “directly connect” to the gate pad as all of these segments 194-2, 198-1, 198-2 and 198-3 only connect to the gate pad through one or more other segments.

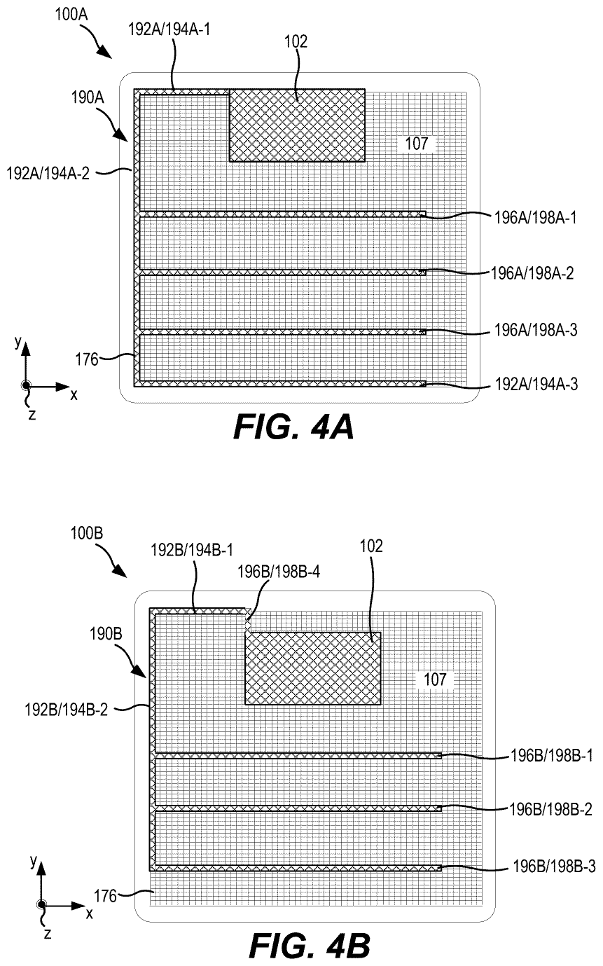

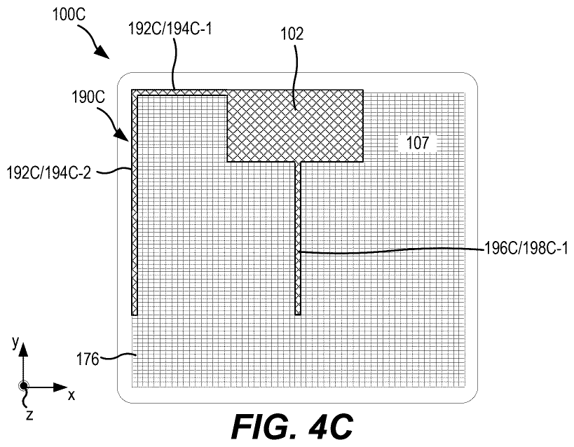

FIGS. 4A-4C are schematic top views of modified versions of the silicon carbide power MOSFET 100 of FIGS. 3A-3E that show the locations of the metal gate pad, the metal gate runners and the gate electrodes on the semiconductor layer structure while omitting all other upper dielectric and metallization layers.

Referring first to FIG. 4A, a power MOSFET 100A is shown that may be identical to power MOSFET 100 except that the outer segment 192A of the metal gate runner 190A included in power MOSFET 100A extends all of the way along the left side 107L of the active region 107 and a third outer segment 194A-3 is provided that extends along most of the bottom side 107B of the active region 107. Extending the outer gate runner 192A in this fashion increases the switching speed, as the gate signal will need to travel along a lesser amount of high resistance region when spreading throughout the gate electrode mesh. This improvement in switching speed, however, comes at a cost of an increase in the on-state resistance since the amount of active region is reduced by the increase in the size of the metal gate runner 190A.

Referring to FIG. 4B, a power MOSFET 100B is shown that may be identical to power MOSFET 100 except that (1) the gate pad 102 is moved downwardly so that it is surrounded by the active region 107 and (2) the inner gate runner 196B further includes a fourth, vertically-extending, inner segment 198B-4 that connects the gate pad 102 to the outer gate runner 192B. This design allows the gate pad 102 to distribute the gate signal directly to a larger number of gate electrodes 176 since the active region 107 surrounds the gate pad 102, which allows power MOSFET 100B to have improved switching performance as compared to that of power MOSFET 100.

Referring to FIG. 4C, a power MOSFET 100C is shown that has a metal gate runner 190C that includes an outer gate runner 192C that has outer segments 194C-1 and 194C-2 that may be the same as the outer segments of outer gate runner 192 of MOSFET 100, and an inner gate runner 196C that incudes a single, vertically-extending inner segment 198C-1 that extends downwardly from the middle of the bottom of the gate pad 102C. The metal gate runner 190C is significantly shorter than the metal gate runner 190, and hence power MOSFET 100C may have a larger active region 107C. However, the distance from the metal gate runner 190C to, for example, the bottom corner of the active region 107 is larger than the comparable distance in MOSFET 100, and hence MOSFET 100C will have a slower switching speed than MOSFET 100.

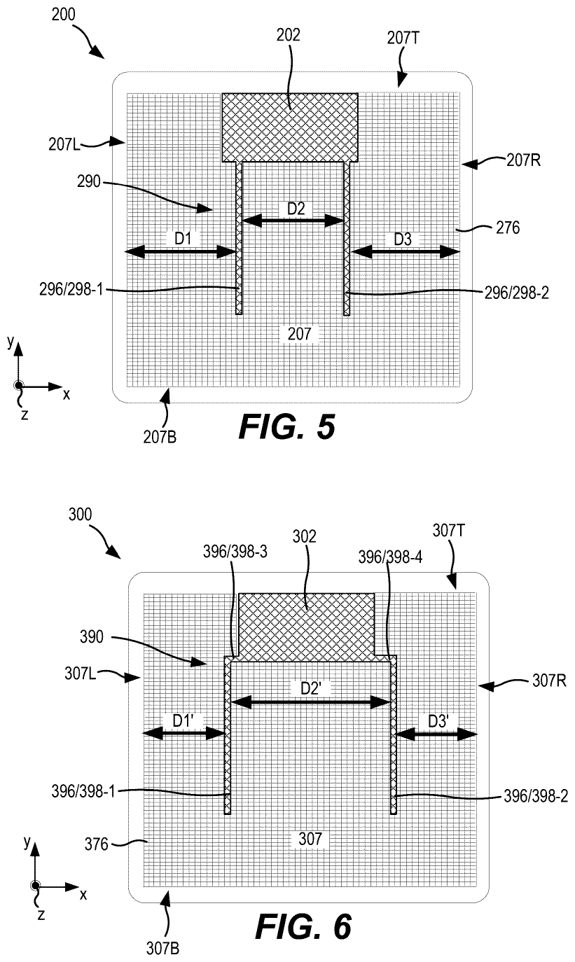

FIG. 5 is a schematic top view of a conventional power MOSFET 200 that has a metal gate runner 290 that comprises an inner gate runner 296 that includes first and second vertically-extending inner segments 298-1, 298-2 and no outer gate runner. MOSFET 200 is illustrated to explain a problem with conventional metal gate runner designs. As can be seen from FIG. 5, the first and second inner segments 298-1, 298-2 provide the primary low-resistance path for distributing gate signals throughout the active region 207 of power MOSFET 200. As shown in FIG. 5, a first distance D1 between the left side 207L of the active region 207 and the first inner segment 298-1 is approximately the same as a second distance D2 between the first vertically-extending inner segment 298-1 and the second inner segment 298-2, and is also approximately the same as a third distance D3 between the second vertically-extending inner segment 298-2 and the right side 207L of the active region 207.

As discussed above, the resistance of the metal gate runner 290 is orders of magnitude less than the resistance of the polysilicon gate electrodes 276 included in MOSFET 200. Accordingly, the total resistance along any electrical path to a position on a gate electrode 276 will be driven almost exclusively by the distance the gate signal travels along the gate electrode(s) 276 to reach the given position. In power MOSFET 200, for the gate electrodes positioned in between the first and second inner segments 298-1, 298-2, the gate signal will travel down one of the first or second inner segments 298-1, 298-2 and then travel across the half of the gate electrode 276 closest to the first or second inner segments 298-1, 298-2. In other words, for these gate electrodes 276, the distance over which the gate signal will travel along a gate electrode is about half the second distance D2. In contrast, for the gate electrodes 276 positioned in between the left side 207L of the active region 207 and the first inner segment 298-1 and for the gate electrodes 276 positioned in between the right side 207R of the active region 207 and the second inner segment 298-2, the gate signal will travel down one of the first or second inner segments 298-1, 298-2 and then must travel all of the way across the gate electrodes 276. Thus, in these regions of the device, the distance over which the gate signal will travel along a gate electrode is either the first distance D1 or the third distance D3. Since the first through third distances D1-D3 are approximately the same, this means that the switching speeds of unit cells along the left and right sides of the device will be much slower than the switching speeds of unit cells in the center of the device. This is non-optimum.

FIG. 6 is a schematic top view of the power MOSFET 300 according to embodiments of the present invention that has a metal gate runner 390 with an inner gate runner 396 that has an improved layout. As can be seen by comparing FIGS. 5 and 6, power MOSFETs 200 and 300 may be identical except that in power MOSFET 300, the positions of the first and second inner segments 398-1, 398-2 are adjusted relative to the positions of the first and second inner segments 298-1, 298-2 in MOSFET 200 so that in MOSFET 300 the second distance D2′ is about twice both the first distance D1′ and the third distance D3′. As a result, the gate signals applied to regions of the gate electrodes 376 that are farthest from the metal gate runner 390 will all travel approximately the same distance along a gate electrode 376. Moreover, the first and third distances D1′, D3′ in power MOSFET 300 are less than the corresponding first and third distances D1, D3 in power MOSFET 200, and hence the switching speed of power MOSFET 300 will be increased relative to power MOSFET 200.

While it may be particularly advantageous to have the second distance D2′ be about twice both the first distance D1′ and/or about twice the third distance D3′, it will be appreciated that embodiments of the present invention are not limited thereto. In fact, as long as D2′ is greater than either D1′ or D3′ and less than four times either D1′ or D3′ then improved switching speed performance may be obtained as compared to the power MOSFET 200. In some embodiments of the present invention, the second distance D2′ may be at least 1.1 times either or both the first distance D1′ and the third distance D3′. In other embodiments, the second distance D2′ may be at least 1.2 times, 1.3 times, 1.5 times or 1.7 times either or both the first distance D1′ and the third distance D3′. In some embodiments of the present invention, the second distance D2′ may be between 1.7 and 2.3 times either or both the first distance D1′ and the third distance D3′.

Still referring to FIG. 6, it can be seen that pursuant to some embodiments of the present invention, semiconductor devices such as MOSFET 300 are provided that comprise a semiconductor layer structure having an active region 307 therein, a gate pad 302 on the semiconductor layer structure, a plurality of gate electrodes 376, and a metal gate runner 390 that electrically connects the gate pad 302 to at least some of the gate electrodes 376. The metal gate runner 390 does not extend along a first side 307L of the active region 307. The metal gate runner 390 comprises an inner gate runner 396 that comprises a plurality of inner segments 398 that extend in parallel to each other and to the first side 307L of the active region 307 when the MOSFET 300 is viewed in plan view. A first distance D2′ between two adjacent ones of the inner segments 398 is at least 1.1 times greater than a second distance D1′ between the first side 307L of the active region 307 and a one of the plurality of inner segments 398-1 that is closest to the first side 307L of the active region 307.

In some embodiments, the first distance D2′ is at least 1.5 times greater than the second distance D1′. In some embodiments, the first distance D2′ is between 1.7 and 2.3 times the second distance D1′. In some embodiments, the inner segments 398 may extend in parallel to each other more than half way across the active region 307. In some embodiments, at least one of the inner segments 398 may extend from the gate pad 302.

Still referring to FIG. 6, it can be seen that pursuant to other embodiments of the present invention, semiconductor devices such as MOSFET 300 are provided that comprise a semiconductor layer structure having an active region 307 therein, a gate pad 202 on the semiconductor layer structure, a plurality of gate electrodes 376, and a metal gate runner 390 that electrically connects the gate pad 302 to at least some of the gate electrodes 376. The metal gate runner 390 comprises a first segment 398-1 and a second segment 398-2 that is adjacent the first segment 398-1, the first and second segments 398-1, 398-2 extending in parallel to each other and to a first side 307R of the active region 307 which does not include any segment of the metal gate runner 390. A first distance D2′ between the first and second segments 398-1, 398-2 is at least 1.1 times greater than a second distance D3′ between the first side 307R of the active region 307 and a one of the first and second segments 398-2 that is closest to the first side 307R of the active region 307.

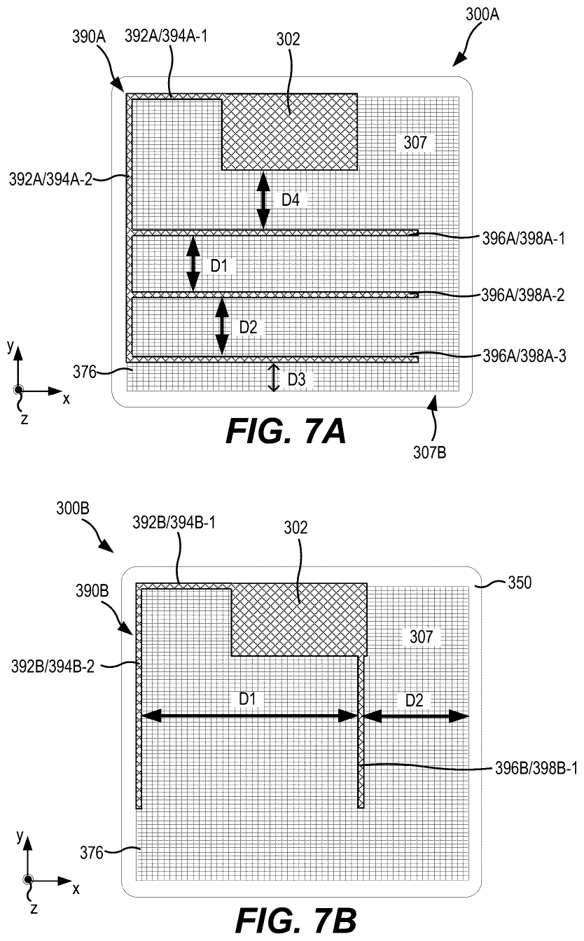

The same technique that is discussed above with reference to FIGS. 5 and 6 may be applied to a wide variety of different metal gate runner designs. For example, FIGS. 7A and 7B are schematic top views of power MOSFETs 300A, 300B according to two additional embodiments of the present invention that have metal gate runners with outer gate runners that only directly connect to a gate pad at one location and metal gate runners that have parallel segments with uneven spacings.

Referring first to FIG. 7A, the power MOSFET 300A is schematically depicted that is similar to power MOSFET 100 of FIGS. 3A-3E, except that in power MOSFET 300A a metal gate runner 390A is provided in which the horizontally-extending inner segments 398-1 through 398-3 of the inner gate runner 396 are unevenly spaced. In particular, the distance D1 between the first and second inner segments 398-1 and 398-2 is substantially equal to the distance D2 between the second and third inner segments 398-2 and 398-3, while the distance D3 between third inner segment 398-3 and the bottom side 307B of the active region 307 is smaller than the distance D1 and the distance D2. In some embodiments, the distance D3 may be about half the distance D1 and/or about half the distance D2. The distance D4 between the first inner segment 398-1 and the first outer segment 394-1 of the outer gate runner 392 of the metal gate runner 390 may be substantially the same as the distances D1 and D2 in some embodiments, as shown. In other embodiments, it may be advantageous to have the distance D4 be less than the distance D1 or the distance D2, since the gate pad 302 does not extend as far to the right as do the inner segments 398A-1 through 398A-3.

Still referring to FIG. 7A, it can be seen that pursuant to some embodiments of the present invention, semiconductor devices such as MOSFET 300A are provided that comprise a semiconductor layer structure having an active region 307 therein, a gate pad 302 on the semiconductor layer structure, a plurality of gate electrodes 376, and a metal gate runner 390A that electrically connects the gate pad 302 to at least some of the gate electrodes 376. The metal gate runner 390A comprises an outer gate runner 392A having a first outer segment 394A-1 and an inner gate runner 396A that comprises a plurality of inner segments 398A that extend from the first outer segment 394A-1 in parallel to each other when the MOSFET 300A is viewed in plan view, where a first distance D4 between the gate pad 302 and a one of the plurality of inner segments 398A-1 that is closest to the gate pad 302 is less than a second distance D2 between two adjacent ones 398A-2, 398A-3 of the plurality of inner segments 398A.

Notably, power MOSFET 300A of FIG. 7A shows that the technique of having the metal gate runner only extend from one side of the gate pad may be combined with the technique of having the spacing between adjacent inner segments of a metal gate runner be larger than the spacing between an outermost one of the inner segments and a side of the active region that does not include an outer segment of the metal gate runner.

FIG. 7B is a schematic plan view of the gate pad and metal gate runner of a power MOSFET 300B that is identical to power MOSFET 100C, except that the inner segment 398B-1 of the inner gate runner 396B of the metal gate runner 390B of power MOSFET 300B is positioned farther to the right than the corresponding inner segment 198C-1 of the inner gate runner 196C of the metal gate runner 190C of power MOSFET 100C. As a result, in power MOSFET 300B the distance D1 is greater than the distance D2, whereas in power MOSFET 100C the corresponding distances are about the same. As shown in FIG. 7B, in some embodiments, the distance D1 may be about twice the distance D2. It will be appreciated, however, that in other embodiments the distance D1 may merely be greater than the distance D2 and less than four times the distance D2. In example embodiments, the distance D1 may be at least 1.1 times, 1.2 times, 1.3 times, 1.5 times or 1.7 times the distance D2, and/or less than 3.5 times, less than 3 times or less than 2.5 times the distance D2. In some embodiments, the distance D1 may be between 1.5 and 2.5 times the distance D2 or between 1.7 and 2.3 times the distance D2.

MOSFET 300B illustrates that a spacing between an inner segment and an outer segment of a metal gate runner may be different than a spacing between the inner segment and a side of the active region that does not include any segment of the metal gate runner. It will be understood that herein references to a “segment” of a metal gate runner that do not specify that the segment is an inner segment or an outer segment refer to a segment that may be either an inner segment or an outer segment.

Thus, as shown in FIG. 7B, pursuant to further embodiments of the present invention, a semiconductor device in the form of power MOSFET 300B is provided that comprises a semiconductor layer structure 350 having an active region 307 therein. A gate pad 302 is provided on the semiconductor layer structure 350. A plurality of gate electrodes 376 are formed on an upper surface of the semiconductor layer structure 350 (and/or in trenches in the semiconductor layer structure 350). A metal gate runner 390B electrically connects the gate pad 302 to at least some of the gate electrodes 376. The metal gate runner 390B includes a first segment 394B-2 and a second segment 398B-1 that is adjacent the first segment 394B-2, where the first and second segments 394B-2, 398B-1 extend in parallel to each other and to a first side (the right side) of the active region 307, where the first side of the active region 307 does not include any segment of the metal gate runner 390B. A first distance D1 between the first and second segments 394B-2, 398B-1 is at least 1.1 times greater than a second distance D2 between the first side of the active region 307 and a one of the first and second segments 398B-1 that is closest to the first side of the active region 307.

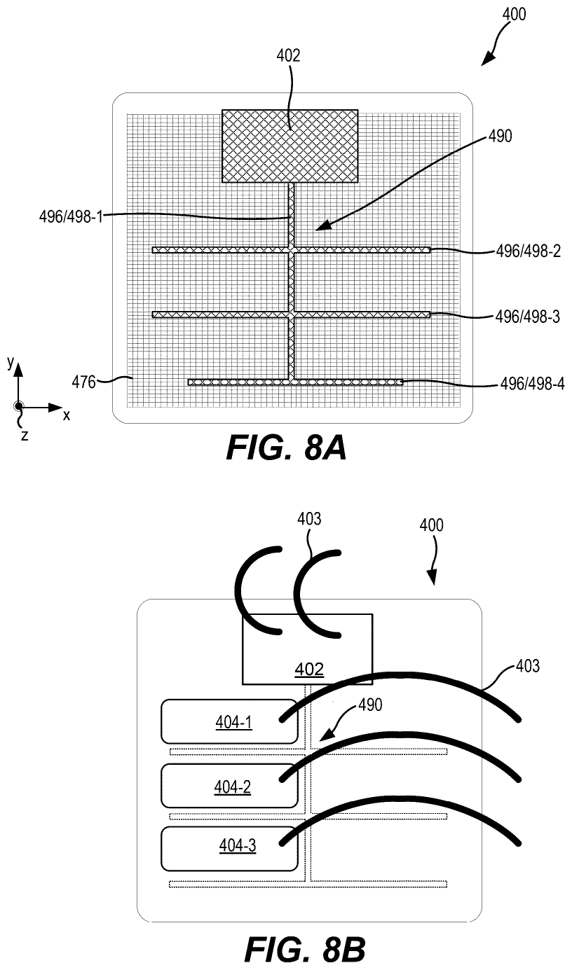

FIG. 8A is a schematic top view of a power MOSFET 400 according to embodiments of the present invention that has a metal gate runner 490 that comprises a spine and multiple ribs. As shown in FIG. 8A, the metal gate runner 490 includes an inner gate runner 496 but does not include any outer gate runner. The inner gate runner 496 includes four inner segments 498, namely a vertically-extending inner segment 498-1 that extends downwardly from the bottom center of the gate pad 402 and three parallel horizontal inner segments 498-2 through 498-4 that intersect the vertically-extending inner segment 498-1. The vertically-extending inner segment 498-1 may be referred to herein as a “spine” and the horizontal inner segments 498-2 through 498-4 may be referred to as “ribs.” The length of each rib may be adjusted to meet a specific gate resistance target, and the distance between the end of each rib and an adjacent edge of the active region may impact current crowding, so the length of the ribs may also be adjusted based on current crowding considerations. Thus, it will be appreciated that the lengths of different ribs may be different, as shown in FIG. 8A.

As discussed above, the switching performance of a power MOSFET may be improved if the maximum distance between the metal gate runner of the MOSFET and any portion of a gate electrode is reduced, as this ensures that the maximum time required to distribute a gate signal to all portions of the active region is minimized. Generally speaking, the more the average distance from the metal gate runner to all positions along all of the gate electrodes is reduced the better the switching performance of the power MOSFET. At the same time, however, it is desirable to keep the amount of die area used to implement the metal gate runner small, as the more area devoted to the metal gate runner the smaller the active region, which negatively impacts the on-state resistance performance of the power MOSFET.

Inner gate runners may be preferred over outer gate runners because outer gate runners may be more prone to delamination. In addition, inner gate runners of a metal gate runner may be more effective at reducing the amount of die area used to implement the metal gate runner than outer gate runners. However, one problem with using inner gate runners having a larger number of inner segments is that the source metallization/source pads and the gate pads/metal gate runners are typically all formed in a single process using a single metal layer, and hence the source pads often cannot vertically overlap the metal gate runner. Thus, any metal gate runner design should leave sufficient room for the source pads so that the source pads can be connected to external circuits (e.g., via bond wires). As a result, conventional power MOSFETs having a metal gate runner with a spine/rib design have typically only had a single internal rib.

FIG. 8B is a schematic top view of a power MOSFET of FIG. 8A that shows the gate pad 402 and the source pads 404-1 through 404-3 and the bond wires 403 connecting thereto. As shown in FIG. 8B, the ribs of the inner gate runner 496 are spaced sufficiently far apart so that the three source pads 404-1 through 404-3 can be fit in between the ribs.

Referring to FIGS. 8A and 8B, it can be seen that pursuant to some embodiments of the present invention, semiconductor devices such as MOSFET 400 are provided that comprise a semiconductor layer structure having an active region therein, a gate pad 402 on the semiconductor layer structure, a plurality of gate electrodes 476, and a metal gate runner 490 that electrically connects the gate pad 402 to at least some of the gate electrodes 476. The metal gate runner 490 comprises an inner gate runner 496 that comprises a first inner segment 498-1 that extends from the gate pad 402, a second inner segment 498-2 that is perpendicular to the first inner segment 498-1 and that intersects the first inner segment 498-1, and a third inner segment 498-3 that is perpendicular to the first inner segment 498-1 and that intersects the first inner segment 498-1.

In some embodiments, the MOSFET 400 further comprising a first source bond pad 404-2 that is at least partially positioned in between the second inner segment 498-2 and the third inner segment 498-3 when the MOSFET 400 is viewed in plan view. In some embodiments, the inner gate runner 496 further comprises a fourth inner segment 498-4 that is perpendicular to the first inner segment 498-1 and that intersects the first inner segment 498-1. In such embodiments, the MOSFET 400 may further comprise a second source bond pad 404-3 that is at least partially positioned in between the third inner segment 498-3 and the fourth inner segment 498-4 when the MOSFET 400 is viewed in plan view. In some embodiments, the MOSFET 400 may further comprise a third source bond pad 404-1 that is at least partially positioned in between the second inner segment 498-2 and the gate pad 402 when the MOSFET 400 is viewed in plan view.

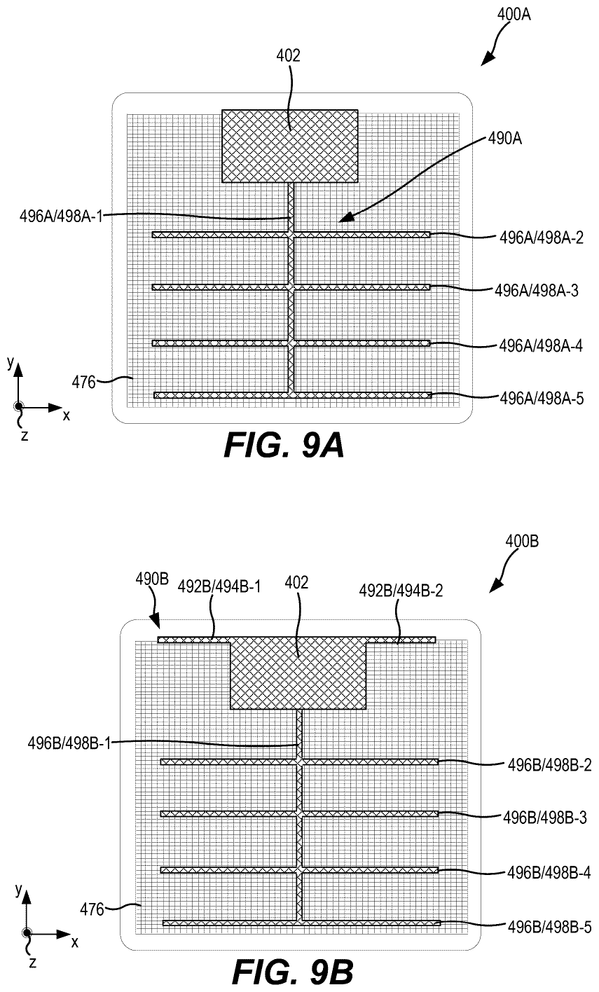

FIGS. 9A-9B are schematic top views of two modified versions of the silicon carbide power MOSFET of FIG. 8A that show the locations of the gate pads, the metal gate runners and the gate electrodes on the semiconductor layer structure while omitting all other upper dielectric and metallization layers. The source bond pads may be positioned in between the ribs in these devices in the same manner as in FIG. 8B.

As can be seen by comparing FIGS. 8A and 9A, power MOSFET 400A is very similar to power MOSFET 400, but further includes a fifth inner segment 498A-4 that extends in both directions from the distal end of the “spine” inner segment 498A-1. In addition, the distances between adjacent pairs of “ribs” and between rib 498A-2 and gate pad 402 have been adjusted in power MOSFET 400A to account for the addition of a fourth rib. As all other aspects of power MOSFET 400A may be identical to power MOSFET 400, further description thereof is omitted here.

As can be seen by comparing FIGS. 9A and 9B, power MOSFET 400B is very similar to power MOSFET 400A, but further includes an outer gate runner 492B that has first and second outer segments 494B-1, 494B-2 that extend horizontally from the respective upper corners of the gate pad 402. Outer segments 494B-1 and 494B-2 reduce the resistance of the outer ends of the gate electrodes 476 that connect directly to the gate pad 402, and hence may improve the switching speed of power MOSFET 400B as compared to power MOSFET 400A. As all other aspects of power MOSFET 400B may be identical to power MOSFET 400A, further description thereof is omitted here

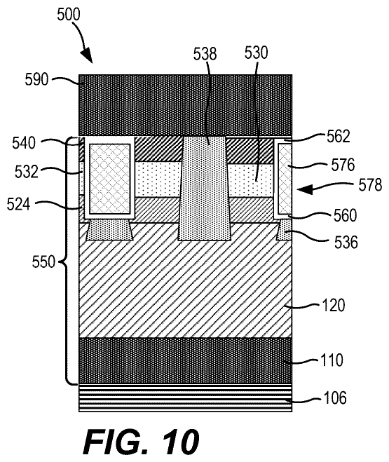

FIG. 10 is a schematic cross-sectional view of a gate trench power MOSFET 500 according to embodiments of the present invention. The plan views of FIGS. 3A and 3B accurately represent power MOSFET 500 as well as power MOSFET 100, and the cross-sectional view shown in FIG. 10 is taken along a vertical cut through box A of FIG. 3B.

As shown in FIG. 10, power MOSFET 500 includes a semiconductor layer structure 550. The semiconductor layer structure 550 includes a substrate 110 and a drift region 120 that may be identical to the like numbered elements of power MOSFET 100 and hence further description thereof will be omitted. The semiconductor layer structure 550 of power MOSFET 500 further comprises a JFET region 524, a plurality of p-wells 530 and a plurality of source regions 540 which may be identical to the similarly numbered elements (i.e., elements with a reference number that is four hundred less than the reference numbers in FIG. 10) of power MOSFET 100 except that the shapes of these regions are different in power MOSFET 500.

As can be seen by comparing FIGS. 3D and 10, power MOSFET 500 primarily differs from power MOSFET 100 in that the gate dielectric layers 560 and gate electrodes 576 of power MOSFET 500 are formed within trenches 578 in the semiconductor layer structure 550 instead of being formed on a planar upper surface of a semiconductor layer structure 150 as is the case with power MOSFET 100. As a result, the channels 532 are formed in the portions of the p-wells 530 that form the sidewalls of the trenches 578. Thus, in power MOSFET 500 the channels 532 are vertical channels whereas in power MOSFET 100 the channel 132 are horizontal channels. As is further shown in FIG. 10, p-type trench shields 536 may be formed underneath each gate trench 578 and/or p-type support shields 538 may be formed in between each pair of gate trenches 578.

Power MOSFET 500 is thus very similar to power MOSFET 100, with the primary difference being that the gate electrodes are formed within trenches 578 in the semiconductor layer structure 550. As such, power MOSFET 500 may look identical to power MOSFET 100 in the view of FIG. 3B. It will be appreciated that the metal gate runner designs according to embodiments of the present invention may be used in power MOSFETs having trench gate electrodes. In fact, any of the power MOSFETs discussed above with respect to FIGS. 3A-9B may have either a planar gate electrode design or a trench gate electrode design.

While the above discussion focuses on power MOSFETs that have mesh gate designs in which the gate electrodes extend in both the horizontal and vertical directions when the power MOSFET is viewed in plan view, it will be appreciated that embodiments of the present invention are not limited thereto. In particular, the techniques disclosed herein may be used in power MOSFETs having gate electrodes that only extend in the horizontal direction (as shown in the power MOSFET of FIG. 1A) and in power MOSFETs having gate electrodes that only extend in the vertical direction (as shown in the power MOSFET of FIG. 1B). In such power MOSFETs, the metal gate runner designs may need to be modified slightly (e.g., the lengths of one or more inner or outer segments may need to be lengthened) so that every gate electrode connects to the metal gate runner, since the individual gate electrodes are not interconnected through a gate electrode mesh. It will also be appreciated that the techniques disclosed herein are equally applicable to power MOSFETs having so-called cell designs where hexagonal or other-shaped unit cells are provided.

While the above discussion focuses on n-channel MOSFETs, it will be appreciated that pursuant to further embodiments of the present invention, the polarity of each of the semiconductor layers in each device could be reversed so as to provide corresponding p-channel MOSFETs. Likewise, while the embodiments of the present invention discussed above are MOSFETs, it will be appreciated that the techniques disclosed herein may also be used to form insulated gate bipolar junction transistors (IGBTs) that include a MOSFET according to embodiments of the present invention, or other gate controlled power semiconductor devices.

Herein, embodiments of the present invention are described with respect to cross-sectional diagrams that show one or two unit cells of a power switching devices. It will be appreciated that actual implementations will typically include a much larger number of unit cells. However, it will also be appreciated that the present invention is not limited to such devices, and that the claims appended hereto also cover MOSFETs and other power switching devices that comprise, for example, a single unit cell. Moreover, while the present disclosure focuses on silicon carbide devices, it will be appreciated that embodiments of the present invention may also have applicability to devices formed using other wide band-gap semiconductors such as, for example, gallium nitride, zinc selenide or any other II-VI or III-V wide band-gap compound semiconductors.

The invention has been described above with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. In the drawings, the size and relative sizes of layers and regions may be exaggerated for clarity. It will be understood that when an element or layer is referred to as being “on”, “connected to” or “coupled to” another element or layer, it can be directly on, connected or coupled to the other element or layer, or intervening elements or layers may be present. In contrast, when an element is referred to as being “directly on,” “directly connected to” or “directly coupled to” another element or layer, there are no intervening elements or layers present. As used herein, the term “and/or” includes any and all combinations of one or more of the associated listed items. Like numbers refer to like elements throughout.

It will be understood that although the terms first and second are used herein to describe various regions, layers and/or elements, these regions, layers and/or elements should not be limited by these terms. These terms are only used to distinguish one region, layer or element from another region, layer or element. Thus, a first region, layer or element discussed below could be termed a second region, layer or element, and similarly, a second region, layer or element may be termed a first region, layer or element without departing from the scope of the present invention.

Relative terms, such as “lower” or “bottom” and “upper” or “top,” may be used herein to describe one element's relationship to another element as illustrated in the drawings. It will be understood that relative terms are intended to encompass different orientations of the device in addition to the orientation depicted in the drawings. For example, if the device in the drawings is turned over, elements described as being on the “lower” side of other elements would then be oriented on “upper” sides of the other elements. The exemplary term “lower” can, therefore, encompass both an orientation of “lower” and “upper,” depending on the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises,” “comprising,” “includes” and/or “including,” when used herein, specify the presence of stated features, elements, and/or components, but do not preclude the presence or addition of one or more other features, elements, components, and/or groups thereof.

Embodiments of the invention are described herein with reference to cross-sectional illustrations that are schematic illustrations. As such, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Thus, the regions illustrated in the figures are schematic in nature and their shapes are not intended to illustrate the actual shape of a region of a device and are not intended to limit the scope of the invention.

It will be understood that the embodiments disclosed herein can be combined. Thus, features that are pictured and/or described with respect to a first embodiment may likewise be included in a second embodiment, and vice versa.

While the above embodiments are described with reference to particular figures, it is to be understood that some embodiments of the present invention may include additional and/or intervening layers, structures, or elements, and/or particular layers, structures, or elements may be deleted. Although a few exemplary embodiments of this invention have been described, those skilled in the art will readily appreciate that many modifications are possible in the exemplary embodiments without materially departing from the novel teachings and advantages of this invention. Accordingly, all such modifications are intended to be included within the scope of this invention as defined in the claims. Therefore, it is to be understood that the foregoing is illustrative of the present invention and is not to be construed as limited to the specific embodiments disclosed, and that modifications to the disclosed embodiments, as well as other embodiments, are intended to be included within the scope of the appended claims. The invention is defined by the following claims, with equivalents of the claims to be included therein.

1. A semiconductor device, comprising:
a semiconductor layer structure having an active region therein;
a gate pad on the semiconductor layer structure, the gate pad positioned to be closest to a first side of the active region;
a plurality of gate electrodes; and
a metal gate runner that electrically connects the gate pad to at least some of the gate electrodes, the metal gate runner comprising an outer runner that extends around a portion of a periphery of the active region,
wherein, when the semiconductor device is viewed in plan view, the outer gate runner comprises a first outer segment that extends along at least a portion of the first side of the active region and a second outer segment that extends along at least a portion of a second side of the active region that connects to the first side, but the outer gate runner does not extend along a third side of the active region that is opposite the second side.

2. The semiconductor device of claim 1, wherein, when the semiconductor device is viewed in plan view, the outer gate runner does not extend along a portion of the first side of the active region that is in between the gate pad and the third side of the active region.

3. (canceled)

4. The semiconductor device of claim 1, wherein the metal gate runner further comprises an inner gate runner that includes a plurality of inner segments that extend inwardly from the outer gate runner.

5. The semiconductor device of claim 4, wherein at least some of the inner segments extend at right angles from the second outer segment of the outer gate runner, and wherein the inner segments that extend from the second outer segment of the outer gate runner do not extend all the way to the third side of the active region.

6. (canceled)

7. The semiconductor device of claim 1, wherein, when the semiconductor device is viewed in plan view, the outer gate runner does not extend along a fourth side of the active region that is opposite the first side of the active region, and wherein the metal gate runner further comprises an inner gate runner that includes a plurality of inner segments that extend inwardly from the outer gate runner.

8. The semiconductor device of claim 7, wherein, when the semiconductor device is viewed in plan view, a first distance between two adjacent ones of the inner segments is at least 1.1 times greater than a second distance between the fourth side of the active region and a one of the inner segments that is closest to the fourth side of the active region.

9. (canceled)

10. The semiconductor device of claim 7, wherein, when the semiconductor device is viewed in plan view, a first distance between two adjacent ones of the inner segments is between 1.7 and 2.3 times a second distance between the fourth side of the active region and a one of the inner segments that is closest to the fourth side of the active region.

11-12. (canceled)

13. The semiconductor device of claim 1, wherein the metal gate runner further comprises an inner gate runner that comprises a first inner segment that extends from the gate pad.

14. The semiconductor device of claim 13, wherein the first inner segment extends in parallel to the second outer segment.

15-16. (canceled)

17. A semiconductor device, comprising:
a semiconductor layer structure having an active region therein;
a gate pad on the semiconductor layer structure;
a plurality of gate electrodes; and
a metal gate runner that electrically connects the gate pad to at least some of the gate electrodes,
wherein the metal gate runner comprises an outer gate runner that partly surrounds the active region when the semiconductor device is viewed in plan view, where the outer gate runner only extends along first and second sides of the active region.

18. The semiconductor device of claim 17, wherein the first side of the active region connects to the second side of the active region.

19. The semiconductor device of claim 18, wherein the outer gate runner only includes a single outer segment that directly connects to the gate pad.

20. The semiconductor device of claim 19, wherein the gate pad is positioned to be closest to the first side of the active region, and the outer gate runner does not extend along a third side of the active region that is opposite the second side of the active region.

21-27. (canceled)

28. The semiconductor device of claim 19, wherein the metal gate runner further comprises an inner gate runner that comprises a first inner segment that extends from the gate pad.

29. The semiconductor device of claim 28, wherein the first inner segment extends in parallel to the second outer segment.

30. (canceled)

31. A semiconductor device, comprising:
a semiconductor layer structure comprising an active region therein;
a gate pad on the semiconductor layer structure;
a plurality of gate electrodes; and
a metal gate runner that includes an outer gate runner that electrically connects the gate pad to at least some of the gate electrodes,
wherein the outer gate runner includes a plurality of outer segments and only a single one of the outer segments directly connects to the gate pad.

32. The semiconductor device of claim 31, wherein, the plurality of outer segments comprises a first outer segment that extends along at least a portion of the first side of the active region and a second outer segment that extends along at least a portion of a second side of the active region that connects to the first side, and the outer gate runner does not extend along a third side of the active region that is opposite the second side.

33. The semiconductor device of claim 31, wherein, when the semiconductor device is viewed in plan view, the outer gate runner does not extend along a fourth side of the active region that is opposite the first side of the active region.

34. The semiconductor device of claim 33, wherein the metal gate runner further comprises an inner gate runner that comprises a plurality of inner segments that extend from the outer gate runner.

35-36. (canceled)

37. The semiconductor device of claim 34, wherein, when the semiconductor device is viewed in plan view, a first distance between two adjacent ones of the inner segments is between 1.7 and 2.3 times a second distance between the fourth side of the active region and a one of the inner segments that is closest to the fourth side of the active region.

38-72. (canceled)
